(19) United States
(12) Patent Application Publication
(10) Pub. No.: US 2024/0388058 A1
(43) Pub. Date: Nov. 21, 2024

(54) SEMICONDUCTOR LIGHT EMITTING DEVICE AND METHOD FOR MANUFACTURING SEMICONDUCTOR LIGHT EMITTING DEVICE

(71) Applicant: ROHM CO., LTD., Kyoto-shi (JP)

(72) Inventor: Akito SHINODA, Kyoto-shi (JP)

(21) Appl. No.: 18/665,144

(22) Filed: May 15, 2024

(30) Foreign Application Priority Data
May 17, 2023 (JP) 2023-081641

(51) Int. Cl. H01S 5/0236; H01S 5/02208; H01S 5/02218; H01S 5/02257; H01S 5/042

(52) U.S. Cl. CPC H01S 5/0236; H01S 5/02208; H01S 5/02218; H01S 5/02257; H01S 5/04256

(57) ABSTRACT

A semiconductor light emitting device includes a substrate, an edge-emitting light emitting element, an adhesion pattern, a cap, an adhesive, and a restriction member. The adhesion pattern has a frame shape surrounding the edge-emitting light emitting element. The cap includes first to fourth side walls and accommodates the edge-emitting light emitting element. The first to fourth side walls are opposed to the adhesion pattern in the Z-direction. The first to fourth side walls have a frame shape and include an opening end surface and an inner side surface. The adhesive bonds the opening end surface of the first to fourth side walls to the pattern surface of the adhesion pattern. The restriction member is disposed on the substrate and is in contact with the inner side surface of the first to fourth side walls so as to restrict movement of the cap in a direction intersecting the Z-direction.

### CROSS-REFERENCE TO RELATED APPLICATIONS

This application is based upon and claims the benefit of priority from prior Japanese Patent Application No. 2023-081641, filed on May 17, 2023, the entire contents of which are incorporated herein by reference.

### BACKGROUND

### 1. Field

The present disclosure relates to a semiconductor light emitting device and a method for manufacturing a semiconductor light emitting device.

### 2. Description of Related Art

A semiconductor light emitting device is known that includes a substrate, a semiconductor light emitting element placed on the substrate, and a cap placed on the substrate to accommodate the semiconductor light emitting element (for example, see Japanese Laid-Open Patent Publication No. 2021-174820). In this semiconductor light emitting device, the cap is bonded to the substrate using an adhesive, for example.

### BRIEF DESCRIPTION OF THE DRAWINGS

FIG. 1 is a perspective view of a semiconductor light emitting device according to a first embodiment.

FIG. 2 is a schematic plan view showing the internal structure of the semiconductor light emitting device shown in FIG. 1.

FIG. 3 is a schematic cross-sectional view of the semiconductor light emitting device taken along line F3-F3 in FIG. 2.

FIG. 4 is a schematic plan view of the semiconductor light emitting device cut along line F4-F4 in FIG. 3.

FIG. 5 is an enlarged schematic cross-sectional view of a part of the cross-sectional structure of the semiconductor light emitting device shown in FIG. 3.

FIG. 6 is an enlarged schematic cross-sectional view of another part of the cross-sectional structure of the semiconductor light emitting device shown in FIG. 3.

FIG. 7 is a schematic cross-sectional view showing a cross-sectional structure taken along line F7-F7 in FIG. 4.

FIG. 8 is a schematic cross-sectional view showing a manufacturing step of the semiconductor light emitting device shown FIG. 1.

FIG. 9 is a schematic cross-sectional view showing a manufacturing step after the step shown in FIG. 8.

FIG. 10 is a schematic cross-sectional view showing a manufacturing step after the step shown in FIG. 9.

FIG. 11 is a schematic cross-sectional view showing a manufacturing step after the step shown in FIG. 10.

FIG. 12 is a schematic cross-sectional view showing a manufacturing step after the step shown in FIG. 11.

FIG. 13 is a schematic cross-sectional view showing a manufacturing step after the step shown in FIG. 12.

FIG. 14 is a schematic cross-sectional view showing a manufacturing step after the step shown in FIG. 13.

FIG. 15 is a schematic cross-sectional view showing a manufacturing step after the step shown in FIG. 14.

FIG. 16 is a schematic cross-sectional view showing a manufacturing step after the step shown in FIG. 15.

FIG. 17 is a schematic plan view showing a manufacturing step after the step shown in FIG. 16.

FIG. 18 is a schematic plan view showing a manufacturing step after the step shown in FIG. 17.

FIG. 19 is a schematic end view showing a manufacturing step after the step shown in FIG. 18.

FIG. 20 is a schematic side view showing a manufacturing step after the step shown in FIG. 19.

FIG. 21 is a schematic side view showing a manufacturing step after the step shown in FIG. 20.

FIG. 22 is a schematic plan view showing the internal structure of a semiconductor device of a modification.

FIG. 23 is a schematic cross-sectional view showing the internal structure of the semiconductor device of the modification.

FIG. 24 is a schematic plan view showing the internal structure of a semiconductor light emitting device according to a second embodiment.

FIG. 25 is a schematic cross-sectional view showing the internal structure of the semiconductor light emitting device shown in FIG. 24.

FIG. 26 is a schematic plan view showing the internal structure of a semiconductor light emitting device of a modification.

FIG. 27 is a schematic cross-sectional view showing the internal structure of the semiconductor light emitting device shown in FIG. 26.

FIG. 28 is a schematic cross-sectional view showing the internal structure of a semiconductor light emitting device of a modification.

FIG. 29 is a schematic plan view showing the internal structure of a semiconductor light emitting device according to a third embodiment.

FIG. 30 is a schematic cross-sectional view showing the internal structure of the semiconductor light emitting device shown in FIG. 29.

FIG. 31 is a schematic cross-sectional view showing the internal structure of a semiconductor light emitting device of a modification.

FIG. 32 is a schematic cross-sectional view showing the internal structure of a semiconductor light emitting device of a modification.

FIG. 33 is a schematic cross-sectional view showing the internal structure of a semiconductor light emitting device of a modification.

FIG. 34 is a schematic cross-sectional view showing a part of the cross-sectional structure of a semiconductor light emitting device of a modification.

FIG. 35 is a schematic cross-sectional view showing the internal structure of a semiconductor light emitting device of a modification.

FIG. 36 is a schematic plan view showing the internal structure of a semiconductor light emitting device of a modification.

Throughout the drawings and the detailed description, the same reference numerals refer to the same elements. The drawings may not be to scale, and the relative size, proportions, and depiction of elements in the drawings may be exaggerated for clarity, illustration, and convenience.

### DETAILED DESCRIPTION

This description provides a comprehensive understanding of the methods, apparatuses, and/or systems described. Modifications and equivalents of the methods, apparatuses, and/or systems described are apparent to one of ordinary skill in the art. Sequences of operations are exemplary, and may be changed as apparent to one of ordinary skill in the art, with the exception of operations necessarily occurring in a certain order. Descriptions of functions and constructions that are well known to one of ordinary skill in the art may be omitted.

Exemplary embodiments may have different forms, and are not limited to the examples described. However, the examples described are thorough and complete, and convey the full scope of the disclosure to one of ordinary skill in the art.

In the drawings, elements may not be drawn to scale for simplicity and clarity of illustration. In a cross-sectional view, hatching may be omitted to facilitate understanding. The accompanying drawings are merely illustrative of embodiments of the disclosure and should not be considered as limiting the disclosure.

The detailed description below includes devices, systems, and methods that are exemplary embodiments of the present disclosure. This detailed description is merely intended for explanatory purposes, and does not intend to limit the embodiments of the present disclosure, nor the application or usage of such embodiments.

In the following description, the expressions that “the width (dimension) of component A is equal to the width (dimension) of component B”, “the length (dimension) of component A is equal to the length (dimension) of component B”, and “the thickness (dimension) of component A is equal to the thickness (dimension) of component B” refer to that the difference between the width (length, thickness) dimension of component A and the width (length, thickness) dimension of component B is within 10% of the width (length, thickness) dimension of component A.

### First Embodiment

### Overall Configuration of Semiconductor Light Emitting Device

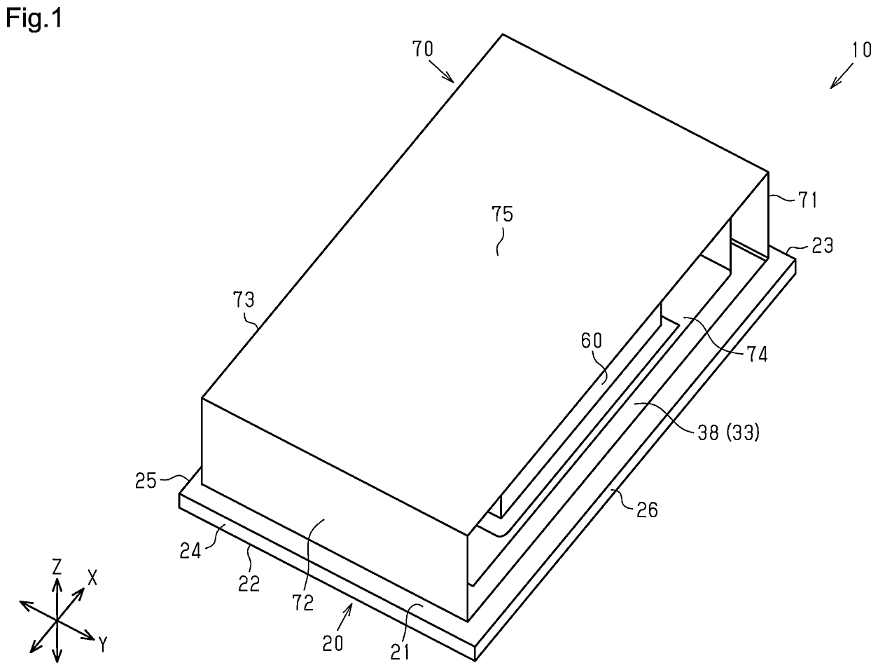

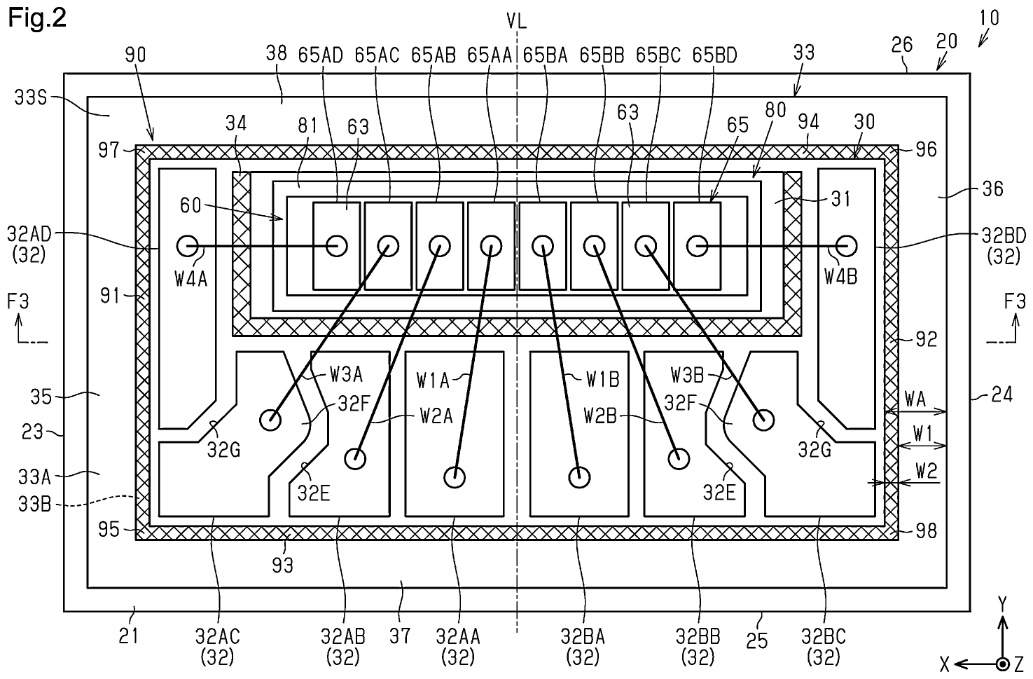

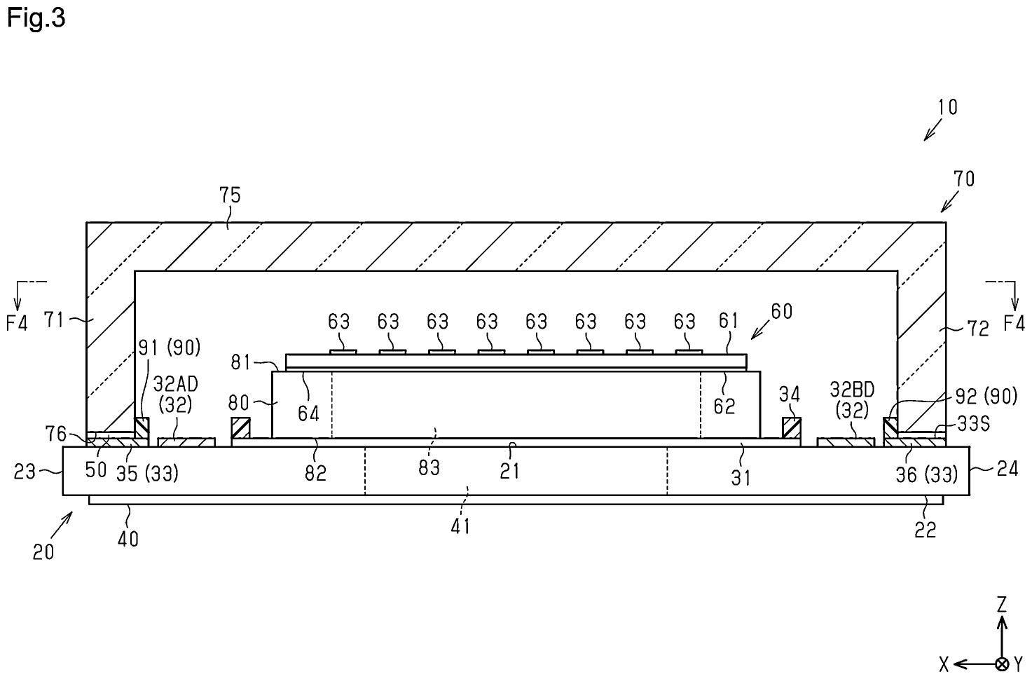

Referring to FIGS. 1 to 3, the overall configuration of a semiconductor light emitting device 10 according to a first embodiment is now described. FIG. 1 shows the perspective structure of a semiconductor light emitting device 10. FIG. 2 schematically shows the planar structure inside the semiconductor light emitting device 10. FIG. 3 shows a cross-sectional structure of the semiconductor light emitting device 10 taken along line F3-F3 in FIG. 2. To facilitate the understanding of the drawing, wires W, which will be described below, are omitted in FIG. 3.

As shown in FIG. 1, the semiconductor light emitting device 10 includes a rectangular flat substrate 20, an edge-emitting light emitting element 60 placed on the substrate 20 (see FIG. 2), and a cap 70, which is placed on the substrate 20 and accommodates the edge-emitting light emitting element 60. The thickness direction of the substrate 20 is referred to as a Z-direction. The Z-direction may also be considered as the thickness direction of the semiconductor light emitting device 10. Of the directions perpendicular to the Z-direction, two perpendicular directions are referred to as the X-direction and the Y-direction. Furthermore, as used herein, plan view refers to viewing the semiconductor light emitting device 10 from the thickness direction (Z-direction) of the substrate 20. In the example of FIG. 1, the substrate 20 is formed in a rectangular shape having a longitudinal direction in the X-direction and a transverse direction in the Y-direction in plan view.

The substrate 20 includes a substrate surface 21 and a substrate back surface 22, which face away from each other in the Z-directions, and first to fourth substrate side surfaces 23 to 26, which intersect the substrate surface 21 and the substrate back surface 22. In the first embodiment, the substrate surface 21 and the substrate back surface 22 are both formed as planes perpendicular to the Z-direction. In one example, the first to fourth substrate side surfaces 23 to 26 are planes perpendicular to the substrate surface 21 and the substrate back surface 22. The first and second substrate side surfaces 23 and 24 form opposite end surfaces of the substrate 20 in the X-direction, and the third and fourth substrate side surfaces 25 and 26 form opposite end surfaces of the substrate 20 in the Y-direction.

In one example, the substrate 20 is made of glass epoxy resin. The substrate 20 may be made of a material containing ceramic. Examples of the material containing ceramic include aluminum nitride (AlN) and alumina (Al₂O₃). When the substrate 20 is made of a material containing ceramic, the heat dissipation performance of the substrate 20 is improved. This limits an excessive increase in the temperature of the edge-emitting light emitting element 60.

As shown in FIG. 2, the edge-emitting light emitting element 60 may be a laser diode that emits light in a predetermined wavelength band, and functions as a light source of the semiconductor light emitting device 10. The edge-emitting light emitting element 60 is an edge-emitting laser element. There is no particular limitation on the edge-emitting light emitting element 60 as an edge-emitting laser device. For example, a Fabry-Perot laser diode may be used. In one example, the edge-emitting light emitting element 60 is configured to emit light toward the fourth substrate side surface 26 in plan view. The edge-emitting light emitting element 60 corresponds to “a semiconductor light emitting element.” The edge-emitting light emitting element 60 also corresponds to “a semiconductor laser element.”

The semiconductor light emitting device 10 includes multiple (nine in the example of FIG. 2) surface electrodes 30 formed on the substrate surface 21 of the substrate 20. The surface electrodes 30 are spaced apart from each other. The surface electrodes 30 are formed of copper foil and gold (Au) plating formed on the copper foil, for example. The material of the surface electrodes 30 is not limited to copper (Cu) and Au. The material may include at least one of aluminum (Al), nickel (Ni), palladium (Pd), or silver (Ag).

The surface electrodes 30 include an element surface electrode 31 and multiple (eight in the example of FIG. 2) wire connection electrodes 32. The element surface electrode 31 and the wire connection electrodes 32 are surface electrodes electrically connected to the edge-emitting light emitting element 60.

The element surface electrode 31 is located closer to the fourth substrate side surface 26 than the center of the substrate surface 21 in the Y-direction. The element surface electrode 31 has a rectangular shape having a longitudinal direction in the X-direction and a transverse direction in the Y-direction. In one example, the dimension of the element surface electrode 31 in the X-direction is greater than twice the dimension in the Y-direction and less than four times the dimension in the Y-direction. In one example, the dimension of the element surface electrode 31 in the X-direction is greater than ½ of the dimension of the substrate surface 21 in the X-direction.

A resist pattern 34 is formed around the element surface electrode 31. The resist pattern 34 is formed in a U-shape that surrounds the element surface electrode 31 at opposite sides in the X-direction, and the side corresponding to the third substrate side surface 25 in the Y-direction in plan view. The resist pattern 34 may be made of an insulating material. The insulating material may be epoxy resin, for example.

The wire connection electrodes 32 are arranged so as to surround the element surface electrode 31. More specifically, the wire connection electrodes 32 are arranged at opposite sides of the element surface electrode 31 in the X-direction, and the side of the element surface electrode 31 closer to the third substrate side surface 25. The wire connection electrodes 32 are not located at the side of the element surface electrode 31 closer to the fourth substrate side surface 26. It may be considered that the wire connection electrodes 32 are arranged so as to surround the edge-emitting light emitting element 60. Details of the wire connection electrodes 32 will be described below.

The semiconductor light emitting device 10 includes a submount substrate 80 mounted on the element surface electrode 31. In one example, the submount substrate 80 is die-bonded to the element surface electrode 31. The submount substrate 80 is a substrate that supports the edge-emitting light emitting element 60 and is made of a material containing ceramic, for example. Examples of the material containing ceramic include AlN and Al₂O₃. When the submount substrate 80 is made of a material containing ceramic, the heat dissipation performance of the submount substrate 80 is improved. This facilitates the transmission of heat from the edge-emitting light emitting element 60 to the substrate 20 through the submount substrate 80. As a result, the temperature of the edge-emitting light emitting element 60 is unlikely to be excessively high.

The material of the submount substrate 80 may be modified. The submount substrate 80 may be made of a metal material with high conductivity and heat dissipation. For example, the metal material may be Ag, Cu, or the like. In one example, the submount substrate 80 is a rectangular flat plate made of Cu. In another example, the submount substrate 80 may be made of a material containing silicon (Si).

As shown in FIGS. 2 and 3, the submount substrate 80 has the shape of a rectangular flat plate having a thickness direction in the Z-direction. In one example, the submount substrate 80 is rectangular and has a longitudinal direction in the X-direction and a transverse direction in the Y-direction in plan view. In one example, the submount substrate 80 has a smaller size than the element surface electrode 31 in plan view.

As shown in FIG. 3, the submount substrate 80 has a greater thickness than the substrate 20. The thickness of the submount substrate 80 may be modified, and may be less than or equal to the thickness of the substrate 20, for example.

The submount substrate 80 has a front surface 81 and a back surface 82, which face away from each other in the Z-direction. In the example of FIG. 3, the front and back surfaces 81 and 82 are both formed as planes perpendicular to the Z-direction. The front surface 81 faces the same side as the substrate surface 21, and the back surface 82 faces the same side as the substrate back surface 22. The edge-emitting light emitting element 60 is mounted on the front surface 81 of the submount substrate 80. In one example, the edge-emitting light emitting element 60 is die-bonded to the front surface 81 of the submount substrate 80.

The submount substrate 80 includes a through-substrate interconnection 83, which extends through the submount substrate 80 in the thickness direction. The through-substrate interconnection 83 electrically connects the edge-emitting light emitting element 60 to the element surface electrode 31. The through-substrate interconnection 83 may be made of a material containing Cu. The material of the through-substrate interconnection 83 is not limited to Cu, and may include at least one of titanium (Ti), tungsten (W), or Al. The number of through-substrate interconnections 83 may be modified. In one example, multiple through-substrate interconnections 83 are provided.

When the submount substrate 80 is made of a conductive material such as Cu, the through-substrate interconnection 83 can be omitted. That is, the conductive submount substrate 80 may electrically connect the edge-emitting light emitting element 60 to the element surface electrode 31.

As shown in FIGS. 2 and 3, the edge-emitting light emitting element 60 mounted on the submount substrate 80 has the shape of a rectangular flat plate having a thickness direction in the Z-direction. The edge-emitting light emitting element 60 is rectangular and has a longitudinal direction in the X-direction and a transverse direction in the Y-direction in plan view. In one example, the edge-emitting light emitting element 60 has a smaller size than the submount substrate 80 in plan view.

The thickness of the edge-emitting light emitting element 60 is less than the thickness of the submount substrate 80. The thickness of the edge-emitting light emitting element 60 is less than the thickness of the substrate 20. Nevertheless, the thickness of the edge-emitting light emitting element 60 may be modified. For example, the thickness may be greater than or equal to the thickness of the substrate 20 or greater than or equal to the thickness of the submount substrate 80.

The edge-emitting light emitting element 60 includes an element surface 61 and an element back surface 62, which face away from each other in the Z-direction. In the example of FIG. 3, the element surface 61 and the element back surface 62 are both formed as planes perpendicular to the Z-direction. The edge-emitting light emitting element 60 includes multiple (eight in the example of FIG. 3) element electrodes 63, which are formed on the element surface 61, and a back electrode 64 forming the element back surface 62. The edge-emitting light emitting element 60 includes a light emitting portion 65 (see FIG. 2) for each element electrode 63. In plan view, the element electrodes 63 are spaced apart in the X-direction. As such, the multiple (eight in the example of FIG. 2) light emitting portions 65 are arranged in the X-direction. Each light emitting portion 65 is configured to emit laser light toward the fourth substrate side surface 26 in plan view.

Each element electrode 63 is rectangular and has a longitudinal direction in the Y-direction and a transverse direction in the X-direction in plan view. In the example of FIG. 3, the element electrodes 63 form the anode electrodes of the respective light emitting portions 65. For example, the back electrode 64 may be formed over the entire element back surface 62 of the edge-emitting light emitting element 60. In the example of FIG. 3, the back electrode 64 forms a common cathode electrode for the multiple light emitting portions 65. The element electrodes 63 and the back electrode 64 may be made of Au, for example. The material of the element electrodes 63 and the back electrode 64 is not limited to Au and may include at least one of Al, Ni, Pd, Ag, or Cu.

The edge-emitting light emitting element 60 is mounted on the submount substrate 80 using a conductive bonding material (not shown). As such, the conductive bonding material electrically connects the back electrode 64 to the submount substrate 80 (through-substrate interconnection 83). The through-substrate interconnection 83 electrically connects the back electrode 64 to the element surface electrode 31. Examples of the conductive bonding material include a solder paste and a silver paste.

As shown in FIG. 2, the semiconductor light emitting device 10 includes wires W1A to W4A and W1B to W4B, which electrically connect the respective light emitting portions 65 to the corresponding wire connection electrodes 32. The wires W1A to W4A and W1B to W4B may be bonding wires, for example. The wires W1A to W4A and W1B to W4B are made of a material containing Au, for example. The wires W1A to W4A and W1B to W4B may be made of a material containing at least one of Cu, Ag, or Al, instead of Au.

As shown in FIG. 3, the semiconductor light emitting device 10 includes multiple (nine in one example) back electrodes 40 formed on the substrate back surface 22 of the substrate 20. The back electrodes 40 are spaced apart from each other. The number of the back electrodes 40 is set according to the number of the surface electrodes 30 (see FIG. 2). The back electrodes 40 may be formed by copper foil and Au plating formed on the copper foil, for example. The material of the back electrodes 40 is not limited to Cu and Au and may include at least one of Al, Ni, Pd, or Ag.

Although not shown, the back electrodes 40 include an element back electrode and multiple (eight in one example) wire back electrodes. The element back electrode is electrically connected to the element surface electrode 31. The wire back electrodes are electrically connected to the respective wire connection electrodes 32 (see FIG. 2) formed on the substrate surface 21. The back electrodes 40 are electrically connected to the respective surface electrodes 30 by separate through-substrate interconnections 41 (see FIG. 3). Each through-substrate interconnection 41 extends through the substrate 20 in the thickness direction (Z-direction).

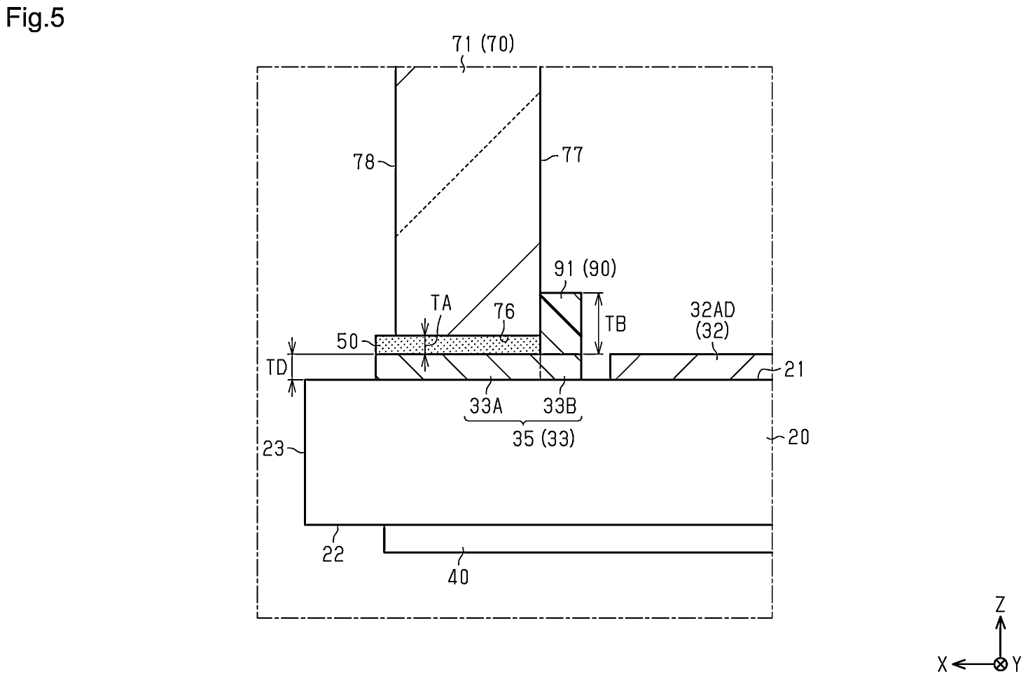

As shown in FIG. 2, the semiconductor light emitting device 10 includes an adhesion pattern 33 formed on the substrate surface 21. The adhesion pattern 33 includes a pattern surface 33S facing the same side as the substrate surface 21. In one example, the adhesion pattern 33 has a frame shape having a predetermined width and extending in a length direction perpendicular to the width. The adhesion pattern 33 has the shape of a frame surrounding the surface electrodes 30 in plan view. In one example, the adhesion pattern 33 has a rectangular frame shape. In the example of FIG. 2, the adhesion pattern 33 has a rectangular frame shape having a longitudinal direction in the X-direction and a transverse direction in the Y-direction. In one example, the outer periphery of the adhesion pattern 33 has a smaller size than the outer periphery of the substrate 20. In one example, the adhesion pattern 33 has the same width dimension WA over the entire perimeter. The width dimension WA of the adhesion pattern 33 is a dimension in a direction perpendicular to the direction in which the adhesion pattern 33 extends (length direction) in plan view. In one example, the thickness dimension TD (see FIG. 5) of the adhesion pattern 33 may be 50 μm or more and 100 μm or less. In one example, the width dimension WA of the adhesion pattern 33 may be 50 μm or more and 500 μm or less.

The adhesion pattern 33 is formed by a metal layer, for example. In one example, the adhesion pattern 33 is made of the same material as the surface electrodes 30. The adhesion pattern 33 may be made of a material different from that of the surface electrodes 30. In one example, the adhesion pattern 33 may be formed by an insulating layer. The adhesion pattern 33 may be made of the same material as the resist pattern 34, for example.

The adhesion pattern 33, which is a metal layer or an insulating layer, slightly protrudes from the substrate surface 21 in the Z-direction. In one example, the thickness of the adhesion pattern 33 is equal to the thickness of the surface electrodes 30, for example. The thickness of the adhesion pattern 33 may be modified, and may be thicker or thinner than the thickness of the surface electrodes 30.

The pattern surface 33S of the adhesion pattern 33 may be formed by a flat surface perpendicular to the Z-direction. An adhesive 50 (see FIG. 3) is applied to the pattern surface 33S of the adhesion pattern 33. The adhesive 50 may be formed over the entire perimeter of the adhesion pattern 33 in plan view, for example. Since the adhesion pattern 33 limits spreading of the adhesive 50, the adhesive 50 is unlikely to extend beyond the adhesion pattern 33.

As shown in FIG. 3, a cap 70 is fixed on the adhesion pattern 33 by the adhesive 50. As such, the cap 70 may be considered to be disposed on the substrate 20. The cap 70 has the shape of a box opening in the Z-direction toward the substrate 20. In one example, the cap 70 is made of a glass material. The cap 70 may be made of a resin material instead of a glass material. Examples of the resin material include acrylic resin and epoxy resin. Also, the cap 70 may be made of metal or ceramic. Examples of the metal include Al, iron (Fe), and Cu. Examples of the ceramic include AlN and Al₂O₃.

As shown in FIG. 1, the cap 70 includes first to fourth side walls 71 to 74, which have a rectangular frame shape in plan view, and an upper wall 75, which closes one of the openings in the Z-directions formed by the first to fourth side walls 71 to 74. The first to fourth side walls 71 to 74 correspond to “a side wall.” In one example, the first to fourth side walls 71 to 74 and the upper wall 75 are integrally formed. The first and second side walls 71 and 72 form side walls at opposite ends of the cap 70 in the X-direction, and the third and fourth side walls 73 and 74 form side walls at opposite ends of the cap 70 in the Y-direction. The first side wall 71 forms one of opposite side walls in the X-direction of the cap 70 that is closer to the first substrate side surface 23 of the substrate 20. The second side wall 72 forms the side wall that is closer to the second substrate side surface 24 of the substrate 20. The third side wall 73 forms one of opposite side walls in the Y-direction of the cap 70 that is closer to the third substrate side surface 25 of the substrate 20. The fourth side wall 74 forms the side wall that is closer to the fourth substrate side surface 26 of the substrate 20. The first to fourth side walls 71 to 74 are opposed to the adhesion pattern 33 in the Z-direction. The first to fourth side walls 71 to 74 have the same shape as the adhesion pattern 33 in plan view. Accordingly, the first to fourth side walls 71 to 74 have a rectangular shape having a longitudinal direction in the X-direction and a transverse direction in the Y-direction in plan view. The first and second side walls 71 and 72, which extend in the Y-direction in plan view, form the sections of the first to fourth side walls 71 to 74 that extend in the transverse direction. The third and fourth side walls 73 and 74, which extend in the x direction in plan view, form the sections of the first to fourth side walls 71 to 74 that extend in the longitudinal direction.

As shown in FIG. 3, the cap 70 includes an opening end surface 76. The opening end surface 76 is formed by the distal end surfaces of the first to fourth side walls 71 to 74. The opening end surface 76 may be formed by a flat surface extending in a direction perpendicular to the Z-direction, for example.

In one example, when the cap 70 is made of a glass material or a resin material, the first to third side walls 71 to 73 and the upper wall 75 are translucent, and the fourth side wall 74 is transparent. The laser light emitted by the edge-emitting light emitting element 60 passes through the fourth side wall 74 and is emitted to the outside of the semiconductor light emitting device 10. That is, the fourth side wall 74 includes a light transmission surface, which transmits the laser light emitted from the edge-emitting light emitting element 60. Since the fourth side wall 74 is opposed to a part of the adhesion pattern 33 in the Z-direction, it may be considered that the cap 70 includes a light transmission surface at a position corresponding to the adhesion pattern 33 in plan view. Also, the fourth side wall 74 forms a section of the first to fourth side walls 71 to 74 that extends in the longitudinal direction. As such, it may be considered that the light transmission surface is formed in a section of the first to fourth side walls 71 to 74 that extends in the longitudinal direction.

In one example, the cap 70 is made of metal or ceramic, and the fourth side wall 74 includes an opening and a window member, which closes the opening and transmits the laser light from the edge-emitting light emitting element 60. The fourth side wall 74 thus includes a light transmission surface.

### Configuration of Wire Connection Electrode

Referring to FIG. 2, the detailed configuration of the wire connection electrodes 32 is now described.

As shown in FIG. 2, the wire connection electrodes 32 are symmetrical with respect to an imaginary center line VL that is at the center of the substrate 20 in the X-direction and extends in the Y-direction in plan view. Hereinafter, of the wire connection electrodes 32, the four wire connection electrodes 32 closer to the first substrate side surface 23 than the imaginary center line VL are referred to as wire connection electrodes 32AA, 32AB, 32AC, and 32AD, and the four wire connection electrodes 32 closer to the second substrate side surface 24 than the imaginary center line VL are referred to as wire connection electrodes 32BA, 32BB, 32BC, and 32BD. The wire connection electrodes 32AA to 32AD are arranged in the order of the wire connection electrodes 32AA, 32AB, 32AC, and 32AD in a direction away from the imaginary center line VL, that is, from the imaginary center line VL toward the first substrate side surface 23. The wire connection electrodes 32BA to 32BD are arranged in the order of the wire connection electrodes 32BA, 32BB, 32BC, and 32BD in a direction away from the imaginary center line VL, that is, from the imaginary center line VL toward the second substrate side surface 24.

The wire connection electrodes 32AA to 32AC and 32BA to 32BC are aligned with the element surface electrodes 31 as viewed from the Y-direction. The wire connection electrodes 32AD and 32BD are arranged separately on opposite sides of the element surface electrode 31 in the X-direction.

Since the wire connection electrodes 32BA to 32BD and the wire connection electrodes 32AA to 32AD are symmetrical with respect to the imaginary center line VL, the following description focuses on the wire connection electrodes 32AA to 32AD, and detailed descriptions of the wire connection electrodes 32BA to 32BD are omitted.

The wire connection electrodes 32AA to 32AC are arranged uniformly in the Y-direction and spaced apart from each other in the X-direction. The wire connection electrodes 32AA to 32AC have the same dimension in the Y-direction.

The wire connection electrode 32AA is rectangular and has a longitudinal direction in the Y-direction and a transverse direction in the X-direction in plan view.

One of end portions in the X-direction of the wire connection electrode 32AB that is closer to the wire connection electrode 32AC includes a recess 32E, which is recessed toward the wire connection electrode 32AA. The recess 32E includes a base surface and two inclined surfaces, which are inclined so as to be farther from the wire connection electrode 32AC in the Y-directions from the base surface. In one example, the base surface of the recess 32E extends in the Y-direction in plan view. One of opposite end surfaces in the X-direction of the wire connection electrode 32AB that is closer to the wire connection electrode 32AA extends in the Y-direction in plan view. The shape of the base surface of the recess 32E in plan view may be modified. In one example, the base surface of the recess 32E has a concave shape in plan view.

The wire connection electrode 32AC includes a protrusion 32F, which protrudes into the recess 32E of the wire connection electrode 32AB, and a cutout section 32G, which is cut out so as to accommodate the wire connection electrode 32AD.

The protrusion 32F includes a distal end surface, which is opposed to the base surface of the recess 32E in the X-direction, and two inclined surfaces parallel to the two inclined surfaces of the recess 32E in plan view. The inclined surfaces of the protrusion 32F are opposed to the inclined surfaces of the recess 32E in the X-direction.

The cutout section 32G is formed in a section of the wire connection electrode 32AC that is in the side farther from the wire connection electrode 32AB in the X-direction and is closer to the element surface electrode 31 in the Y-direction. The cutout section 32G includes a section that is aligned with the protrusion 32F as viewed in the X-direction. The protrusion 32F thus prevents the dimension of the wire connection electrode 32AC in the X-direction from being excessively reduced by the presence of the cutout section 32G.

The wire connection electrode 32AD extends in the Y-direction. The dimension of the wire connection electrode 32AD in the Y-direction is greater than the dimension of the element surface electrode 31 in the Y-direction. In the Y-direction, a section of the wire connection electrode 32AD that protrudes toward the third substrate side surface 25 beyond the element surface electrode 31 extends into the cutout section 32G of the wire connection electrode 32AC. The distal end of the section of the wire connection electrode 32AD extending in the cutout section 32G is tapered corresponding to the shape of the cutout section 32G.

The arrangement relationship between the wire connection electrodes 32AA to 32AD and the light emitting portions 65 is now described.

The light emitting portions 65 include light emitting portions 65AA to 65AD corresponding to the wire connection electrodes 32AA to 32AD, and light emitting portions 65BA to 65BD corresponding to the wire connection electrodes 32BA to 32BD. The light emitting portions 65AA to 65AD are arranged at the same position in the Y-direction and spaced apart from each other in the X-direction. The light emitting portions 65AA to 65AD are arranged in the order of the light emitting portions 65AA, 65AB, 65AC, and 65AD in a direction away from the imaginary center line VL, that is, from the imaginary center line VL toward the first substrate side surface 23. The light emitting portions 65BA to 65BD are arranged in the order of the light emitting portions 65BA, 65BB, 65BC, and 65BD in a direction away from the imaginary center line VL, that is, from the imaginary center line VL toward the second substrate side surface 24.

The wire connection electrode 32AA is aligned with the light emitting portions 65AA and 65AB in the Y-direction in plan view.

The wire connection electrode 32AB is arranged closer to the first substrate side surface 23 than the light emitting portion 65AB in plan view. The wire connection electrode 32AB is aligned with the light emitting portions 65AC and 65AD in the Y-direction in plan view.

The wire connection electrode 32AC is closer to the first substrate side surface 23 than the light emitting portion 65AC in plan view. The wire connection electrode 32AC is also closer to the first substrate side surface 23 than the light emitting portion 65AD in plan view.

The wire connection electrode 32AD is closer to the first substrate side surface 23 than the light emitting portion 65AD in plan view. The wire connection electrode 32AD is opposed to the light emitting portion 65AD in the X-direction in plan view.

The connection configuration is now described in which the light emitting portions 65 of the edge-emitting light emitting element 60 and the wire connection electrodes 32AA to 32AD and 32BA to 32BD are connected by the wires W1A to W4A and W1B to W4B.

The wire W1A connecting the light emitting portion 65AA and the wire connection electrode 32AA is connected to a section of the wire connection electrode 32AA that is on the opposite side of the center in the Y-direction from the light emitting portion 65AA.

The wire W2A connecting the light emitting portion 65AB and the wire connection electrode 32AB is connected to a section of the wire connection electrode 32AB that is on the opposite side of the base surface of the recess 32E from the light emitting portion 65AB in the Y-direction.

The wire W3A connecting the light emitting portion 65AC and the wire connection electrode 32AC is connected to a section of the wire connection electrode 32AC that is substantially at the same position in the Y-direction as the distal end surface of the protrusion 32F.

The wire W4A connecting the light emitting portion 65AD and the wire connection electrode 32AD extends in the X-direction in plan view, for example. In this manner, the wires W1A to W4A are connected to the wire connection electrodes 32AA to 32AD such that the variations in the lengths of the wires W1A to W4A in plan view are reduced.

The wire W1B connecting the light emitting portion 65BA and the wire connection electrode 32BA, the wire W2B connecting the light emitting portion 65BB and the wire connection electrode 32BB, the wire W3B connecting the light emitting portion 65BC and the wire connection electrode 32BC, and the wire W4B connecting the light emitting portion 65BD and the wire connection electrode 32BD are connected to the wire connection electrodes 32BA to 32BD in the same manner as the wires W1A to W4A.

### Configuration of Adhesion Pattern and Surrounding Area

Referring to FIGS. 2 to 6, the detailed structure of the adhesion pattern 33 is now described.

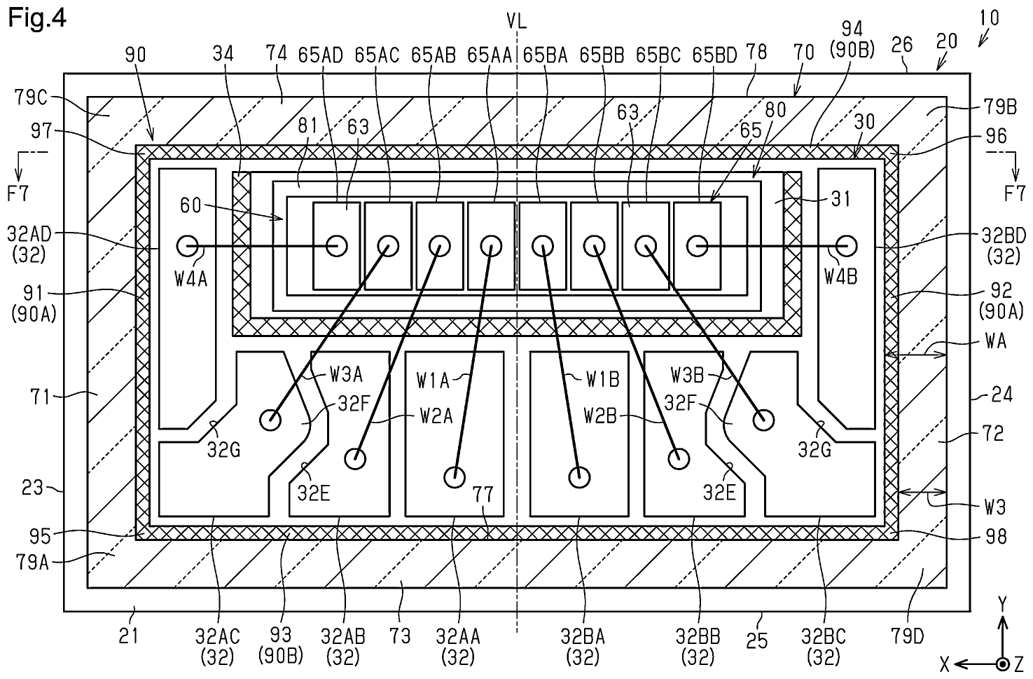

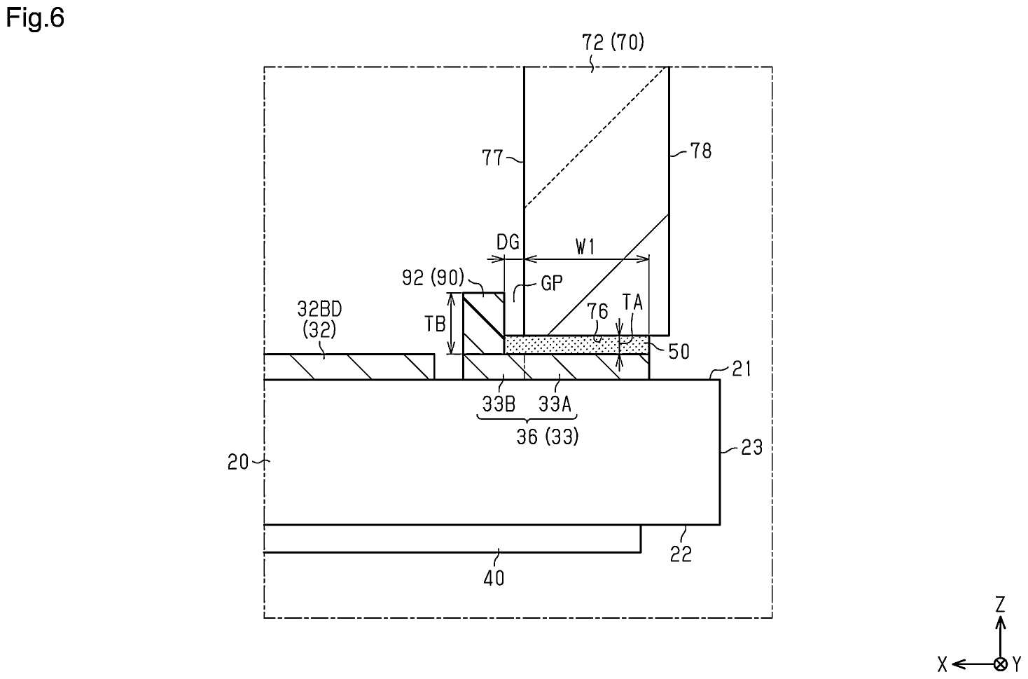

FIG. 4 shows a planar structure of the semiconductor light emitting device 10 in a state in which the cap 70 is cut along line F4-F4 in FIG. 3. FIG. 5 is an enlarged view of a cross-sectional structure of the opening end surface 76 of the first side wall 71 of the cap 70 and its surrounding area in FIG. 3. FIG. 6 is an enlarged view of a cross-sectional structure of the opening end surface 76 of the second side wall 72 of the cap 70 and its surrounding area in FIG. 3.

As shown in FIG. 2, the adhesion pattern 33, which has a rectangular frame shape in plan view, includes a first pattern 35 and a second pattern 36, which are spaced apart from each other in the X-direction, and a third pattern 37 and a fourth pattern 38, which are spaced apart from each other in the Y-direction. The first and second patterns 35 and 36 are both strip-shaped and extend in the Y-direction. The third and fourth patterns 37 and 38 are both strip-shaped and extend in the X-direction. The third pattern 37 and the fourth pattern 38 are connected to opposite ends of the first pattern 35 and the second pattern 36 in the Y-direction, thereby forming the adhesion pattern 33 having a rectangular frame shape

The first pattern 35 is formed at a position adjacent to the first substrate side surface 23 in the X-direction in plan view. The second pattern 36 is formed at a position adjacent to the second substrate side surface 24 in plan view. The first pattern 35 is formed at a position adjacent to the wire connection electrodes 32AC and 32AD in plan view. The second pattern 36 is formed at a position adjacent to the wire connection electrodes 32BC and 32BD in plan view.

The third pattern 37 is formed at a position adjacent to the third substrate side surface 25 in the Y-direction in plan view. The fourth pattern 38 is formed at a position adjacent to the fourth substrate side surface 26 in the Y-direction in plan view. The third pattern 37 is formed at a position adjacent to the wire connection electrodes 32AA to 32AC and 32BA to 32BC in the Y-direction in plan view. The fourth pattern 38 is located at a position adjacent to the element surface electrode 31 and the wire connection electrodes 32AD and 32BD in the Y-direction. As such, it may be considered that the edge-emitting light emitting element 60 is arranged at a position adjacent to the fourth pattern 38 in the Y-direction in plan view.

In the example shown in FIG. 2, the length dimension (dimension in the X-direction) of the third and fourth patterns 37 and 38 is greater than the length dimension (dimension in the Y-direction) of the first and second patterns 35 and 36. That is, the first and second patterns 35 and 36 form the sections of the adhesion pattern 33 that extend in the transverse direction, and the third and fourth patterns 37 and 38 form the sections of the adhesion pattern 33 that extend in the longitudinal direction.

A restriction member 90 is provided on the inner edge portion in the width direction of the adhesion pattern 33. In the example shown in FIG. 2, the restriction member 90 extends over the entire perimeter of the adhesion pattern 33 having a rectangular frame shape. The restriction member 90 therefore has a rectangular frame shape in plan view. Since the restriction member 90 extends over the entire perimeter of the adhesion pattern 33, it may be considered that the restriction member 90 has a frame shape surrounding the edge-emitting light emitting element 60 in plan view. The restriction member 90 may be made of epoxy resin, for example. In one example, the restriction member 90 may be made of the same material as the resist pattern 34.

In plan view, the adhesion pattern 33 includes a first region 33A, in which the adhesive 50 (see FIG. 3) is applied to the pattern surface 33S, and a second region 33B, on which the restriction member 90 is provided. In this embodiment, the first region 33A and the second region 33B each have a rectangular frame shape in plan view. The first region 33A and the second region 33B are arranged in the width direction of the adhesion pattern 33.

In the example shown in FIG. 2, the first region 33A is formed at the outer perimeter portion including the outer edge of the adhesion pattern 33 in plan view. The second region 33B is formed at the inner perimeter portion including the inner edge of the adhesion pattern 33 in plan view.

The first region 33A has a uniform width over the entire perimeter of the adhesion pattern 33. The second region 33B has a uniform width over the entire perimeter of the adhesion pattern 33. The width dimension W1 of the first region 33A is greater than the width dimension W2 of the second region 33B. In one example, the width dimension W1 is twice the width dimension W2 or more. In one example, the width dimension W1 is four times the width dimension W2 or less. In one example, the width dimension W1 is equal to the width dimension W3 of the first to fourth side walls 71 to 74 of the cap 70 (see FIG. 4). The sizes of the width dimension W1 and the width dimension W2 may be modified.

The restriction member 90 includes a first member 91 on the first pattern 35, a second member 92 on the second pattern 36, and a third member 93 on the third pattern 37, and a fourth member 94 on the fourth pattern 38. The first and second members 91 and 92 extend in the Y-direction. The third and fourth members 93 and 94 extend in the X-direction. The length dimension (dimension in the X-direction) of the third and fourth members 93 and 94 is greater than the length dimension (dimension in the Y-direction) of the first and second members 91 and 92. Thus, the first and second members 91 and 92 form sections of the restriction member 90 extending in the transverse direction. The third and fourth members 93 and 94 form sections of the restriction member 90 extending in the longitudinal direction.

The restriction member 90 includes first to fourth corner sections 95 to 98. The first corner section 95 is formed by the connection section between the first and third members 91 and 93. The second corner section 96 is formed by the connection section between the second and fourth members 92 and 94. The third corner section 97 is formed by the connection section between the first and fourth members 91 and 94. The fourth corner section 98 is formed by the connection section between the second and third members 92 and 93.

As shown in FIG. 4, the first to fourth side walls 71 to 74 of the cap 70 are placed on the first region 33A of the adhesion pattern 33 (see FIG. 2). More specifically, the first to fourth side walls 71 to 74 are placed on the adhesive 50 (see FIG. 3) formed on the first region 33A. The adhesive 50 bonds the first to fourth side walls 71 to 74 to the adhesion pattern 33. In this manner, the first to fourth side walls 71 to 74 are placed on a region different from the second region 33B (see FIG. 2). That is, the restriction member 90 is not aligned with the first to fourth side walls 71 to 74 in plan view.

The restriction member 90 having a rectangular frame shape is provided along the entire extent in the perimeter direction of the inner side surface 77 of the first to fourth side walls 71 to 74 in plan view. The restriction member 90 is positioned adjacent to the first to fourth side walls 71 to 74 of the cap 70. More specifically, in plan view, the first member 91 of the restriction member 90 is adjacent to the inner side surface 77 of the first side wall 71 in the X-direction. In plan view, the second member 92 of the restriction member 90 is adjacent to the inner side surface 77 of the second side wall 72 in the X-direction. In plan view, the third member 93 of the restriction member 90 is adjacent to the inner side surface 77 of the third side wall 73 in the Y-direction. In plan view, the fourth member 94 of the restriction member 90 is adjacent to the inner side surface 77 of the fourth side wall 74 in the Y-direction. In plan view, the first corner section 95 of the restriction member 90 is adjacent to the first corner section 79A of the cap 70 in the X and Y-directions. In plan view, the second corner section 96 of the restriction member 90 is adjacent to the second corner section 79B of the cap 70 in the X and Y-directions. In plan view, the third corner section 97 of the restriction member 90 is adjacent to the third corner section 79C of the cap 70 in the X and Y-directions. In plan view, the fourth corner section 98 of the restriction member 90 is adjacent to the fourth corner section 79D of the cap 70 in the X and Y-directions.

The connection section between the first and third side walls 71 and 73 forms the first corner section 79A of the cap 70. The connection section between the second and fourth side walls 72 and 74 form the second corner section 79B. The connection section between the first and fourth side walls 71 and 74 forms the third corner section 79C. The connection section between the second and third side walls 72 and 73 forms the fourth corner section 79D.

As shown in FIGS. 5 and 6, the thickness dimension TB of the restriction member 90 is greater than the thickness dimension TA of the adhesive 50. The restriction member 90 has a uniform thickness dimension TB over its entire perimeter, for example. That is, the thickness dimension of the first member 91, the thickness dimension of the second member 92, the thickness dimension of the third member 93, and the thickness dimension of the fourth member 94 are all equal and the thickness dimension TB. Accordingly, the restriction member 90 includes sections that are opposed to the inner side surface 77 of the first to fourth side walls 71 to 74 of the cap 70. The thickness dimension TB may be about 20 μm, for example.

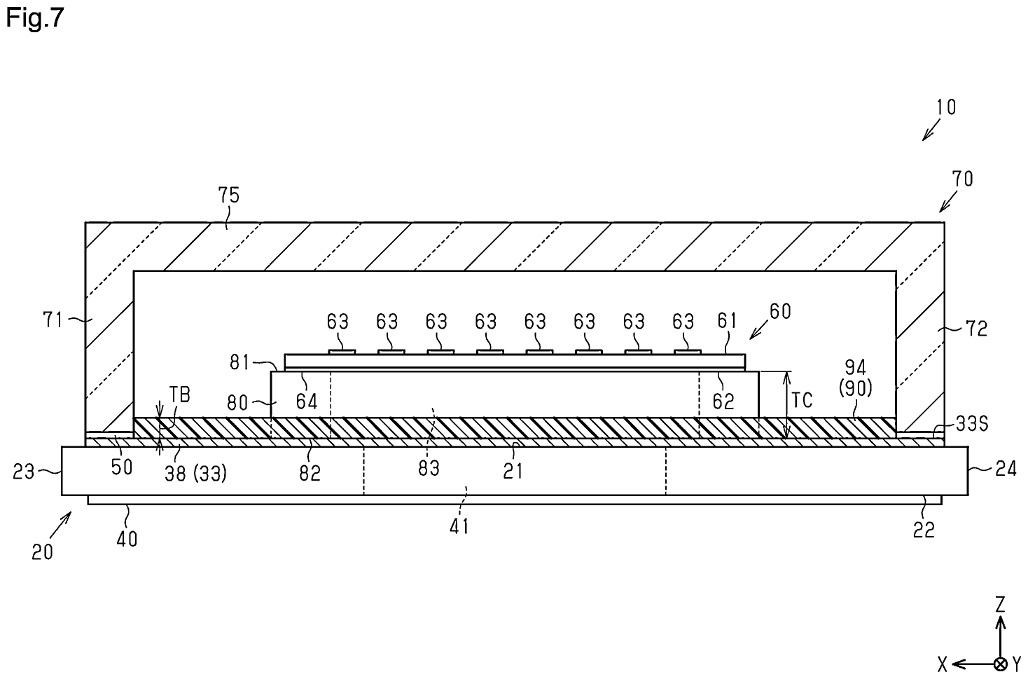

As shown in FIG. 7, the restriction member 90 (fourth member 94) has a thickness dimension TB that is less than the thickness dimension TC of the submount substrate 80. That is, the edge-emitting light emitting element 60 on the submount substrate 80 is closer to the upper wall 75 of the cap 70 than the restriction member 90 in the Z-direction. As such, the laser light from the edge-emitting light emitting element 60 is not applied to the restriction member 90.

Also, the thickness dimension TB of the restriction member 90 may be less than the thickness dimension of the substrate 20, for example. Also, the thickness dimension TB of the restriction member 90 may be less than the thickness dimension TD of the adhesion pattern 33, for example. In FIGS. 3 and 5 to 7, to facilitate understanding of the drawings, the thickness dimension TB of the restriction member 90 is shown to be greater than the thickness dimension TD of the adhesion pattern 33. However, this depiction does not reflect the actual configuration.

The thickness dimension of each of the first to fourth members 91 to 94 may be modified. In one example, the first to fourth members 91 to 94 have different thickness dimensions. In one example, the third member 93 has a greater thickness dimension than the first member 91, the second member 92, and the fourth member 94. In another example, the fourth member 94 has a smaller thickness dimension than the first to third members 91 to 93. The thickness dimension of the fourth member 94 may be set to be greater than the thickness dimension TA of the adhesive 50 and less than or equal to the thickness dimension TC of the submount substrate 80.

According to this configuration of the restriction member 90, the first and second members 91 and 92 restrict movement of the cap 70 in the X-direction. The third and fourth members 93 and 94 restrict movement of the cap 70 in the Y-direction. As such, as shown in FIG. 2, it may be considered that the restriction member 90 includes a first restriction portion 90A, which restricts movement of the cap 70 in the X-direction, and a second restriction portion 90B, which restricts movement of the cap 70 in the Y-direction. In the first embodiment, the first and second members 91 and 92 form the first restriction portion 90A. The third and fourth members 93 and 94 form the second restriction portion 90B.

As shown in FIG. 5, the first member 91 of the restriction member 90 is in contact with the inner side surface 77 of the first side wall 71 of the cap 70, thereby restricting movement of the cap 70 in the X-direction. In this case, as shown in FIG. 6, a gap GP is formed between the second member 92 of the restriction member 90 and the inner side surface 77 of the second side wall 72 of the cap 70 in the X-direction.

The distance DG between the restriction member 90 and the second side wall 72, which forms the gap GP, may be less than the width dimension W1 of the first region 33A, for example. The distance DG may be less than the width dimension W2 (see FIG. 2) of the second region 33B, for example. That is, it may be considered that the distance DG is less than the width dimension of the restriction member 90. The distance DG may be modified as long as the cap 70 is bonded to the adhesive 50 with a predetermined bonding strength or greater.

### Method for Manufacturing Semiconductor Light Emitting Device

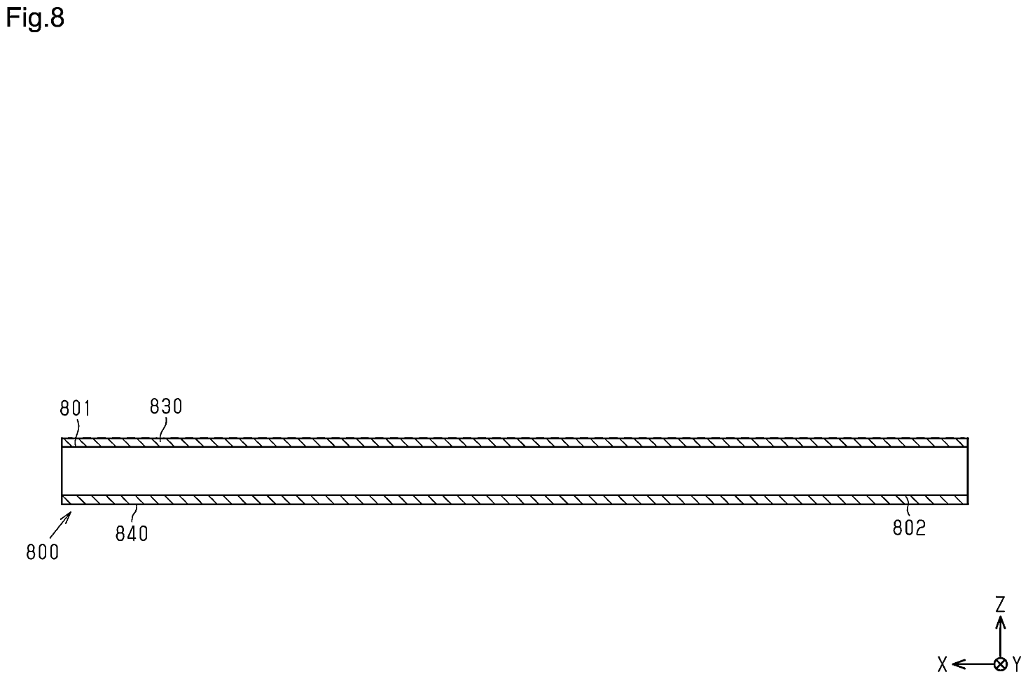

Referring to FIGS. 8 to 21, an example of a method for manufacturing the semiconductor light emitting device 10 is now described.

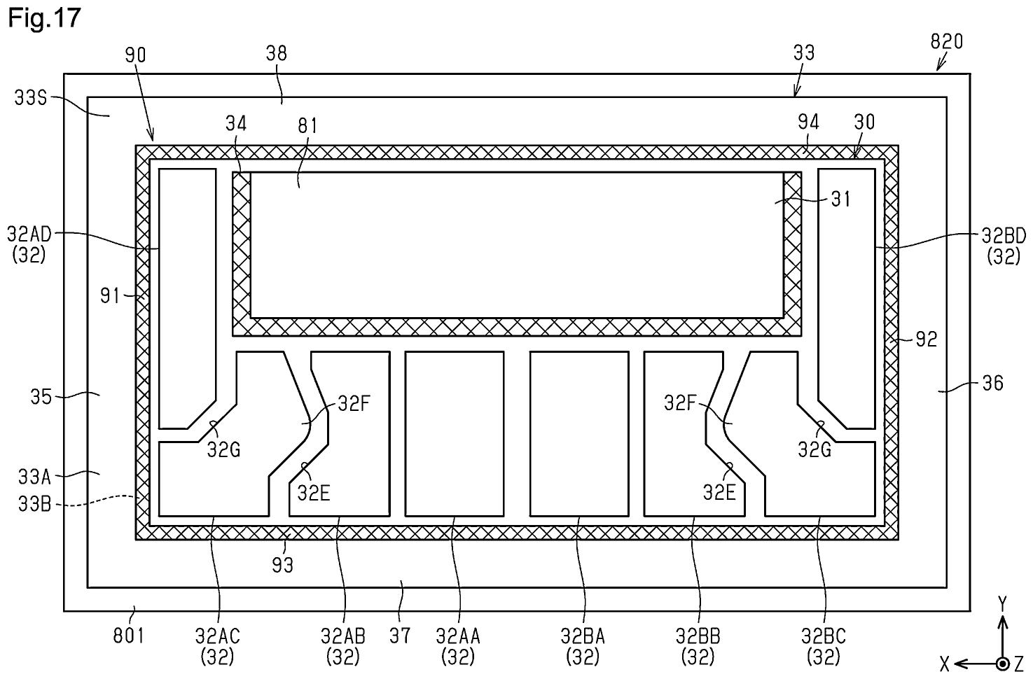

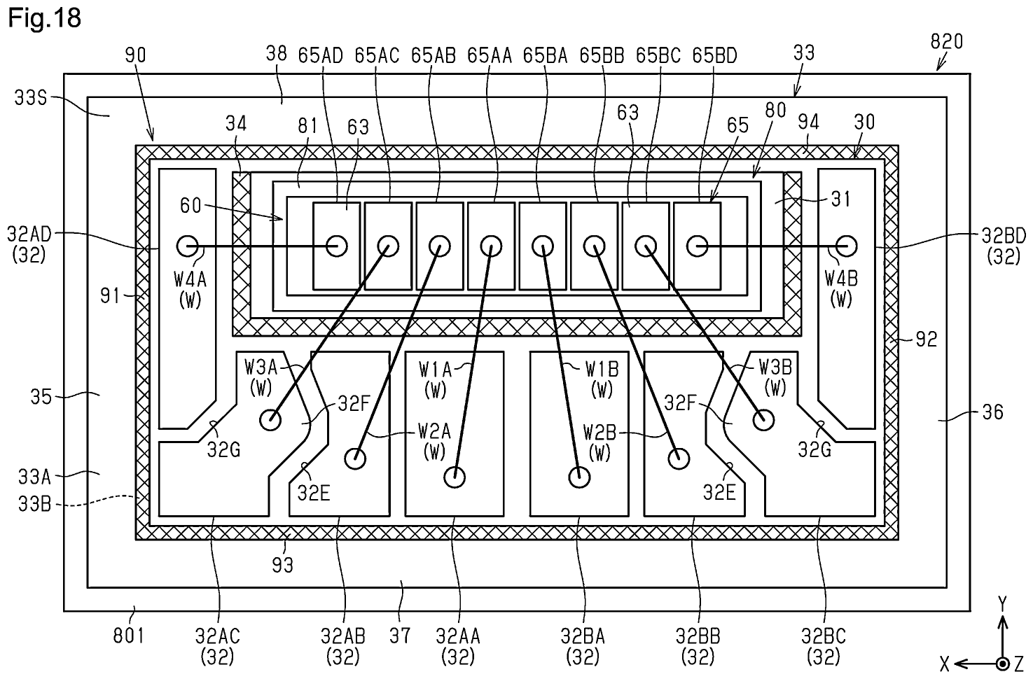

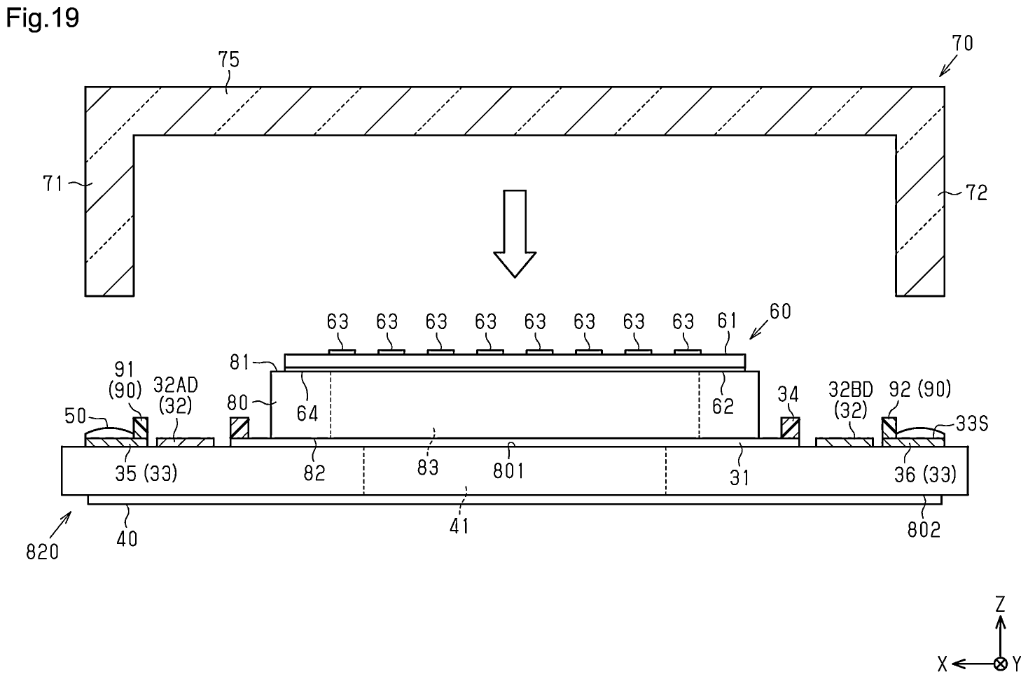

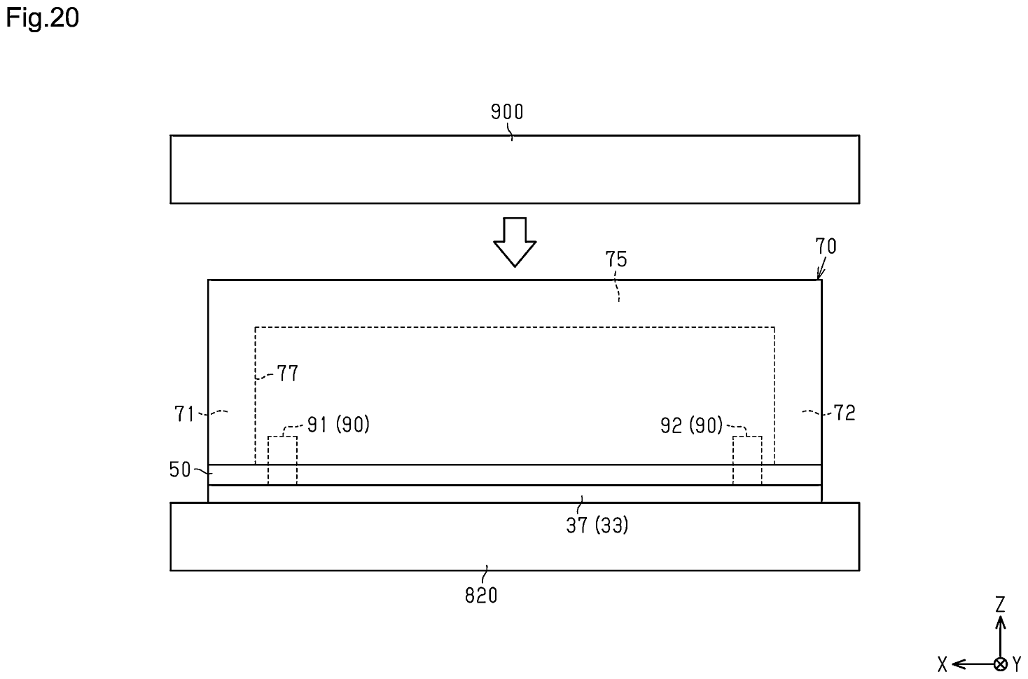

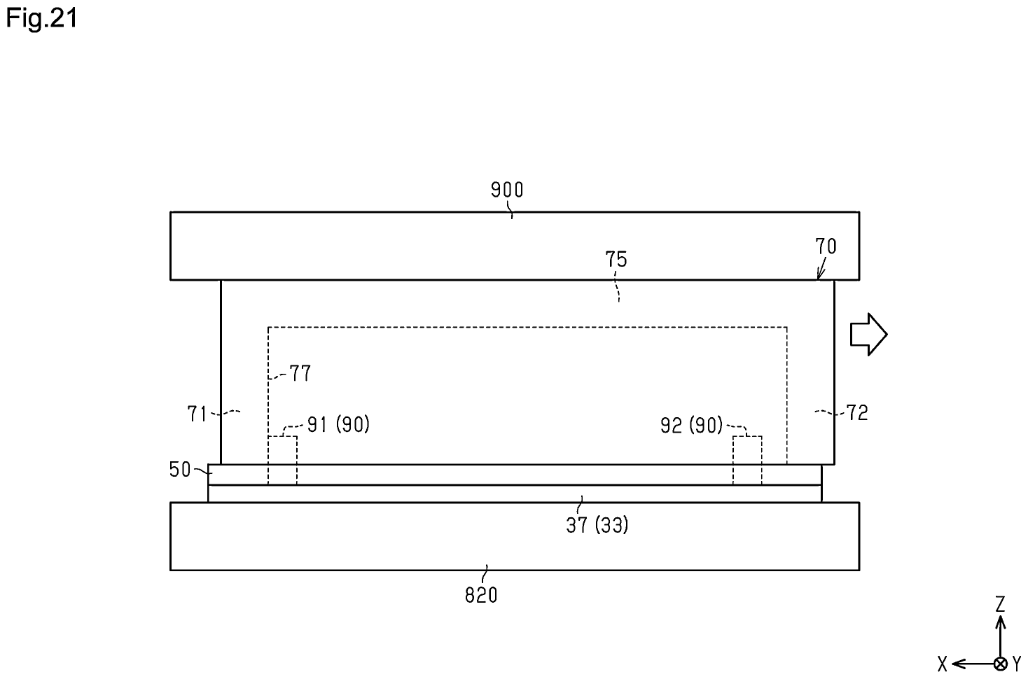

FIGS. 8 to 16 show schematic cross-sectional structures illustrating manufacturing steps of a substrate 820. FIGS. 17 and 18 show planar structures of the substrate 820. FIG. 19 shows a cross-sectional structure illustrating the step of placing the cap 70 on the adhesive 50. FIGS. 20 and 21 show side structures of the substrate 820 and the cap 70 as viewed from the Y-direction. To facilitate the understanding of the drawings, FIGS. 20 and 21 schematically show the substrate 820, the adhesion pattern 33, the adhesive 50, and the cap 70. As such, the ratio of the thickness to the length in the X-direction of each of the substrate 820, the adhesion pattern 33, the cap 70, and the restriction member 90 as illustrated in FIGS. 20 and 21 differs from that in FIG. 3, for example.

As shown in FIGS. 8 to 17, the method for manufacturing the semiconductor light emitting device 10 includes the step of preparing a substrate 820. The step of manufacturing the substrate 820 is now described. The substrate 820 is a member forming the substrate 20.

As shown in FIG. 8, a base material 800 is prepared. The base material 800 includes a base material surface 801 and a base material back surface 802 opposite to the base material surface 801. A surface electrode film 830 is formed on the base material surface 801. A back electrode film 840 is formed on the base material back surface 802. The surface electrode film 830 may be formed over the entire base material surface 801. The back electrode film 840 may be formed over the entire base material back surface 802. The surface electrode film 830 and the back electrode film 840 may be formed by copper foil and gold plating formed on the copper foil, for example. The surface electrode film 830 and the back electrode film 840 are not limited to Cu and Au and may include at least one of Al, Ni, Pd, or Ag.

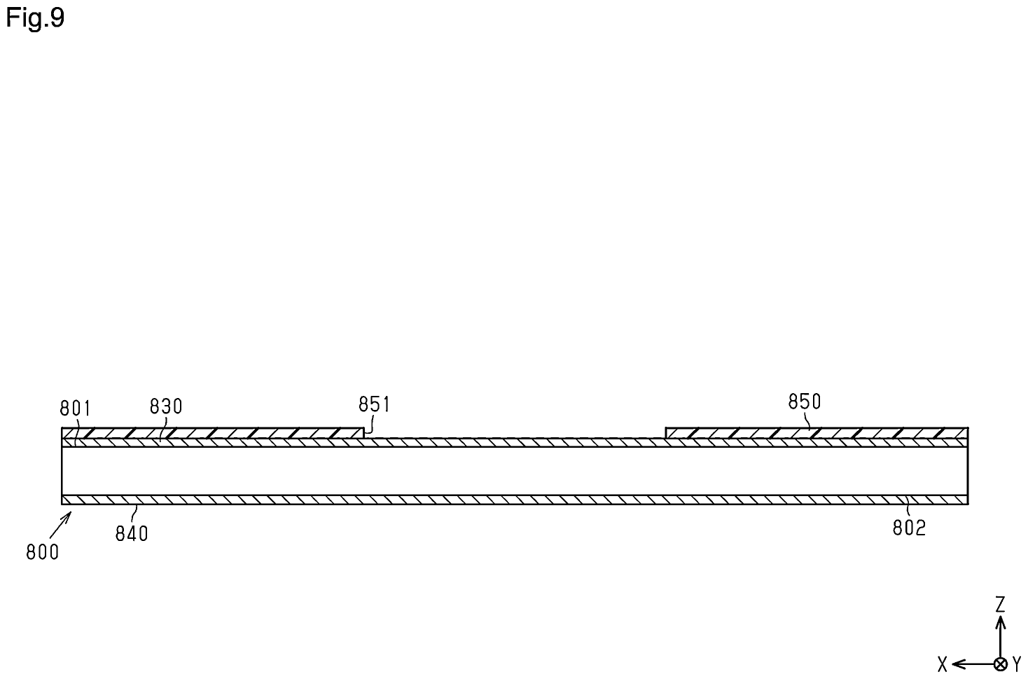

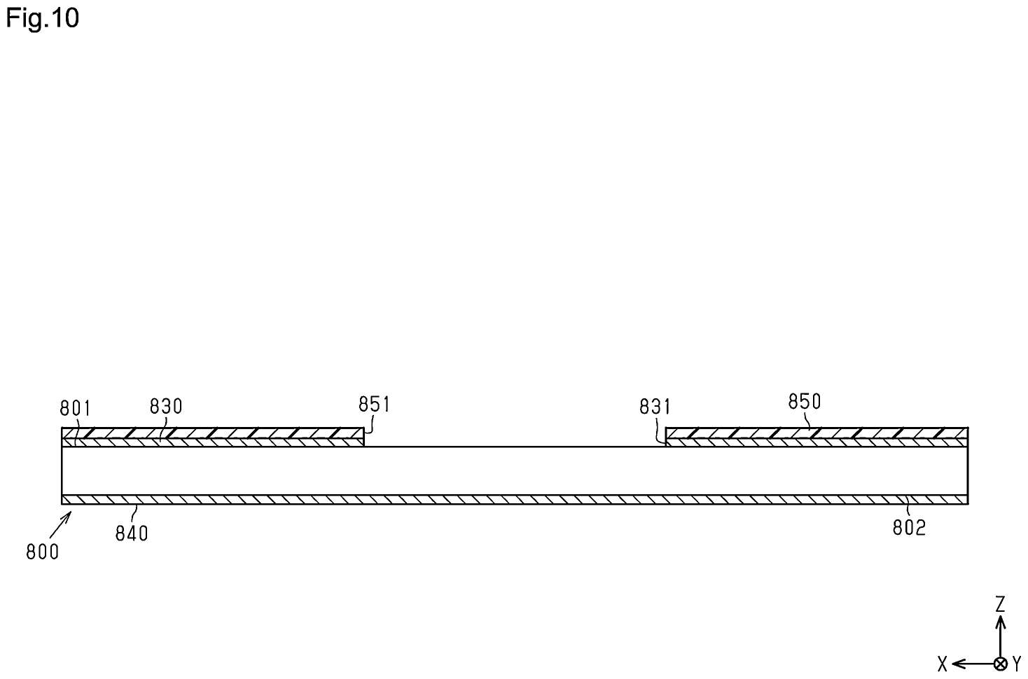

As shown in FIG. 9, a resist 850 is formed on the surface electrode film 830. The resist 850 includes an opening 851, which may be formed by patterning, for example. The opening 851 opens a region of the surface electrode film 830 in which a through-substrate interconnection 41 (see FIG. 3) is to be formed. Then, as shown in FIG. 10, the surface electrode film 830 exposed through the opening 851 is removed by etching, for example. As a result, the base material surface 801 is exposed through the opening 851. The exposed base material surface 801 is a region of the base material 800 in which the through-substrate interconnection 41 is to be formed. As such, the surface electrode film 830 includes the opening 831, which is continuous with the opening 851. The resist 850 is then removed.

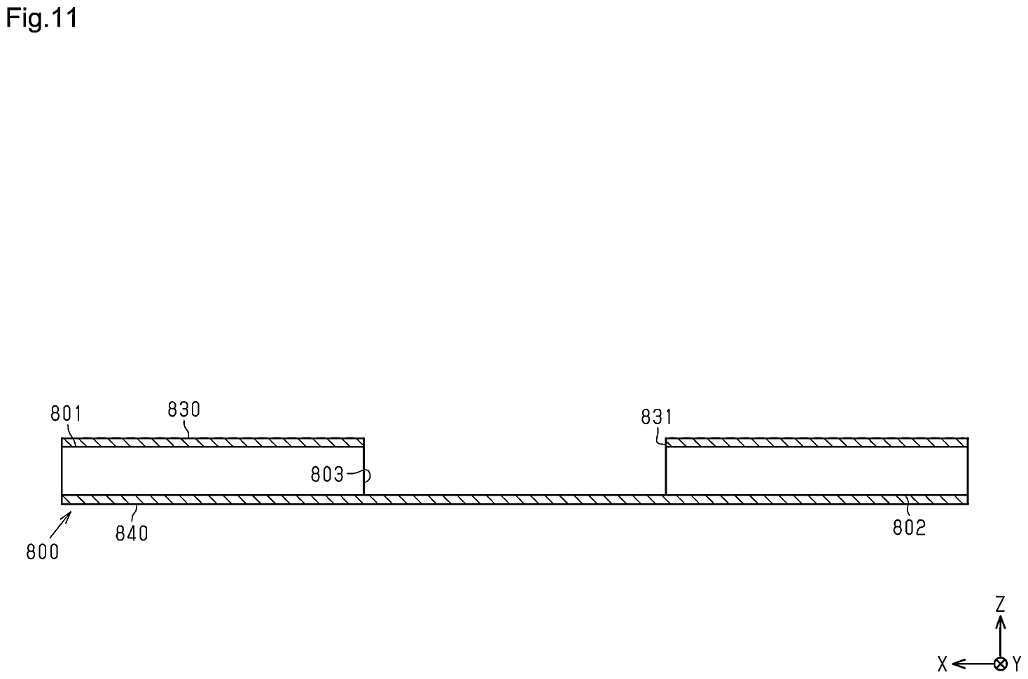

As shown in FIG. 11, a through-hole 803 extending through the base material 800 in the Z-direction is then formed by performing laser processing on the section of the base material 800 that is exposed through the opening 831 of the surface electrode film 830, for example. As a result, the back electrode film 840 is exposed through the through-hole 803.

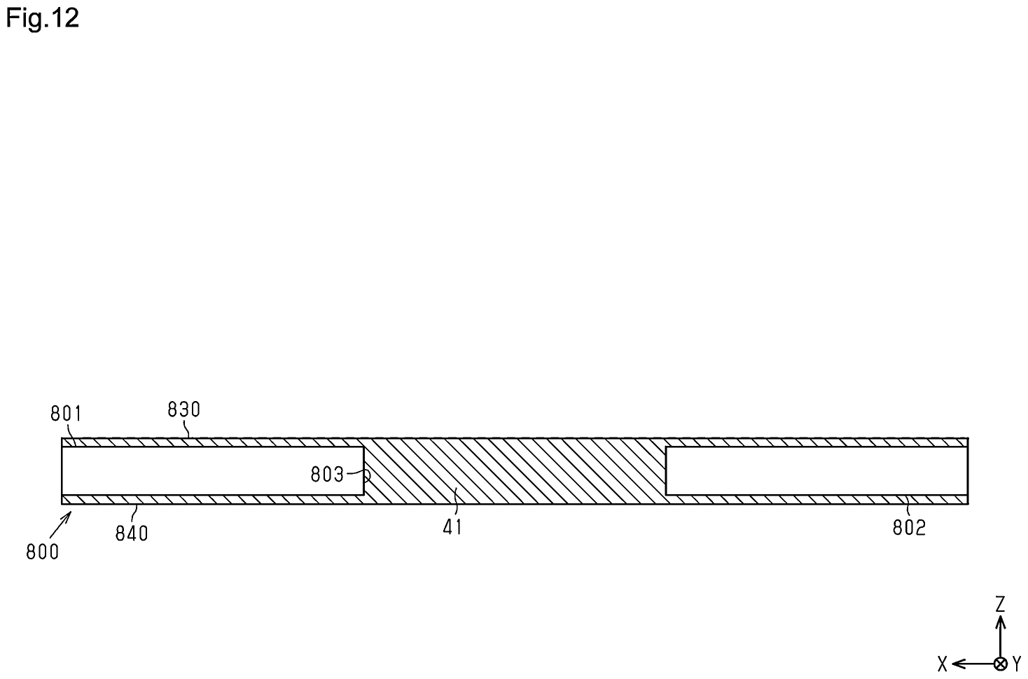

As shown in FIG. 12, a through-substrate interconnection 41 is formed in the through-hole 803 by electroless plating, for example. The through-hole 803 is filled with the through-substrate interconnection 41. The through-substrate interconnection 41 may be made of the same material as the surface electrode film 830 and the back electrode film 840, for example. The through-substrate interconnection 41 is connected to both the back electrode film 840 and the surface electrode film 830.

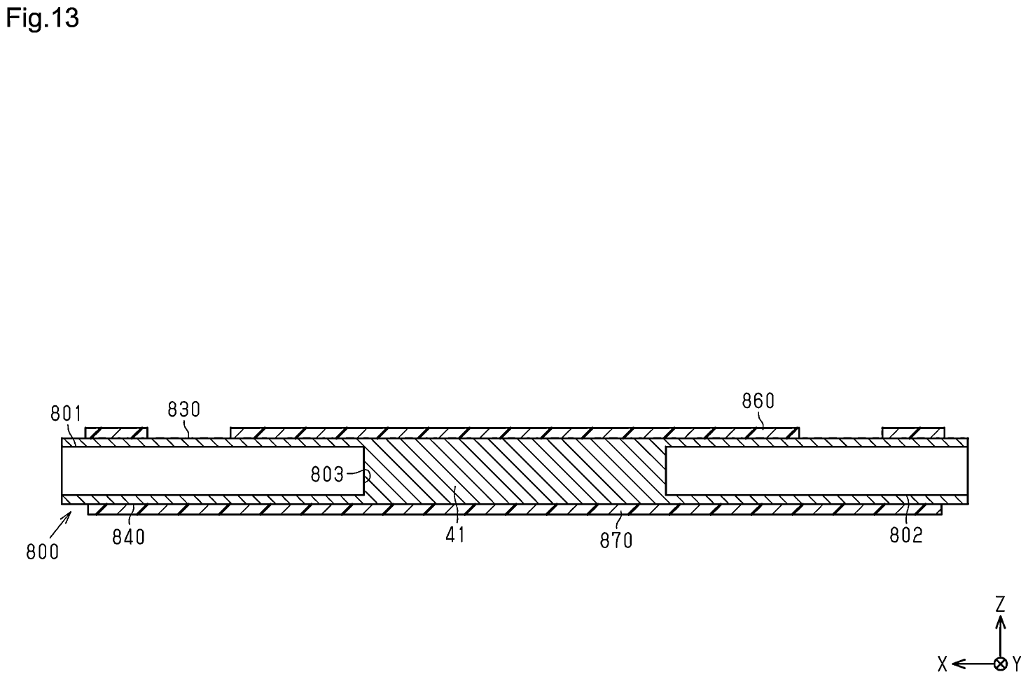

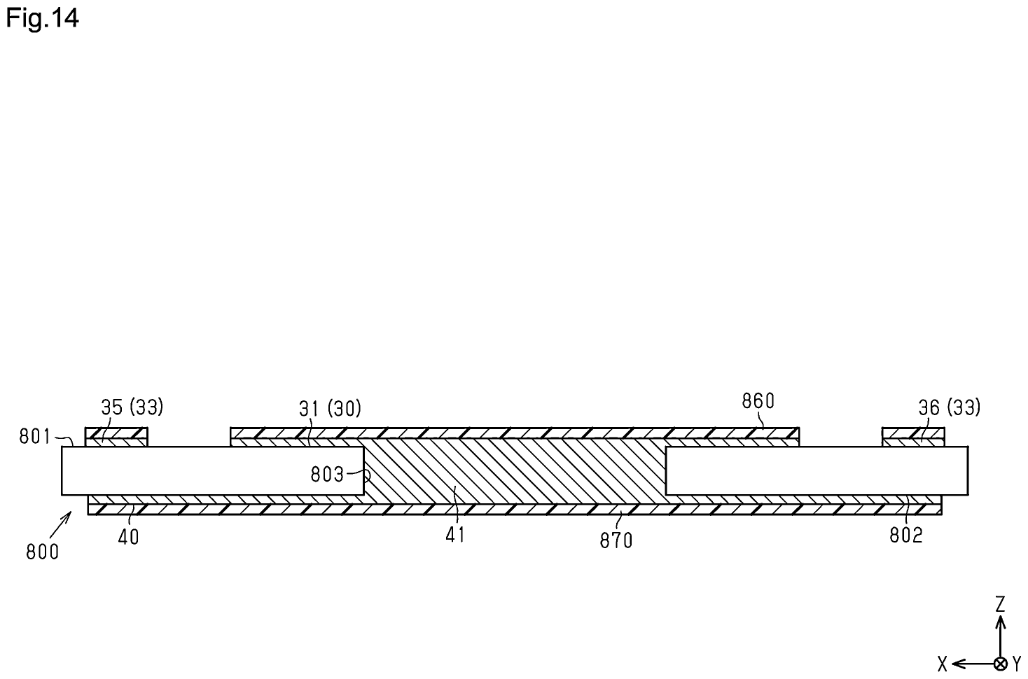

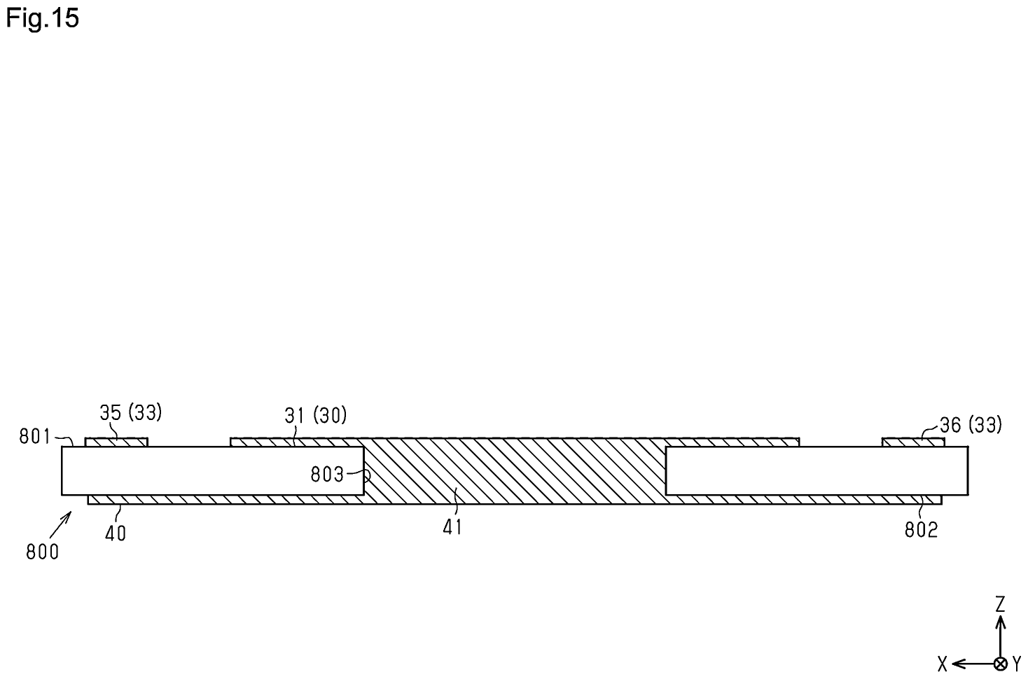

As shown in FIG. 13, a surface resist 860 is then formed on the surface electrode film 830, and a back resist 870 is formed on the back electrode film 840. The surface resist 860 is formed to cover the sections of the surface electrode film 830 that corresponds to the surface electrodes 30 and the section that corresponds to the adhesion pattern 33 (see FIG. 2) by patterning, for example. The back resist 870 is formed to cover the section corresponding to the back electrodes 40 by patterning, for example. As shown in FIG. 14, the sections of the surface electrode film 830 exposed from the surface resist 860 and the sections of the back electrode film 840 exposed from the back resist 870 are then removed by etching. Then, as shown in FIG. 15, both the surface resist 860 and the back resist 870 are removed. As a result, the surface electrodes 30 and the adhesion pattern 33 are formed on the base material surface 801, and the back electrodes 40 are formed on the base material back surface 802.

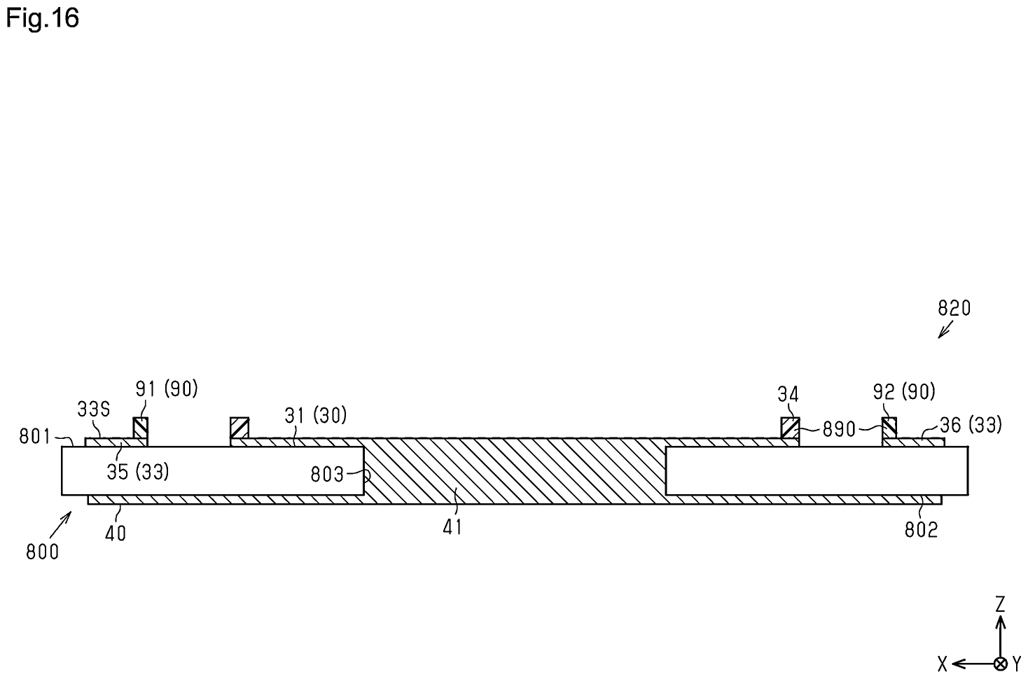

Then, as shown in FIG. 16, a restriction member 90 is formed on the adhesion pattern 33. More specifically, firstly, a resist 890 is formed to cover the entire pattern surface 33S of the adhesion pattern 33, for example. The resist 890 may be epoxy resin. A photomask (not shown) is then formed on the resist 890. The photomask includes an opening through which the section of the resist 890 corresponding to the restriction member 90 (inner perimeter portion in the width direction of the adhesion pattern 33) is exposed. Exposure and development are then performed through the photomask, removing the section of the resist 890 other than the section corresponding to the restriction member 90. The restriction member 90 is thus formed.

In the step of forming the restriction member 90, the resist pattern 34 may be formed at the same time. More specifically, a resist 890 may be formed over the entire surface of the base material surface 801, for example. A photomask is then formed on the resist 890. This photomask includes openings through which both the section of the resist 890 corresponding to the restriction member 90 and the section corresponding to the resist pattern 34 are exposed. Exposure and development are then performed through the photomask, removing the section of the resist 890 other than the section corresponding to the restriction member 90 and the section corresponding to the resist pattern 34. The restriction member 90 and the resist pattern 34 are thus formed. In this manner, the restriction member 90 and the resist pattern 34 may be formed by the common resist 890.

As shown in FIG. 17, the restriction member 90 is formed on the inner perimeter portion including the inner edge of the adhesion pattern 33 along the entire perimeter of the adhesion pattern 33. That is, the restriction member 90 has a rectangular frame shape in plan view. The resist pattern 34 is provided at both of the end portions of the element surface electrode 31 in the X-direction and one of the end portions in the Y-direction that is closer to the third pattern 37 of the adhesion pattern 33. The resist pattern 34 is U-shaped and opens toward the fourth pattern 38 of the adhesion pattern 33, for example. The substrate 820 is manufactured through the above steps.

After the step of preparing the substrate 820 shown in FIGS. 8 and 17, the method for manufacturing the semiconductor light emitting device 10 mainly includes the steps of placing a submount substrate 80 on the substrate 820, placing an edge-emitting light emitting element 60 on the submount substrate 80, and forming wires W1A to W4A and W1B to W4B (see FIG. 2). In the following description, the wires W1A to W4A and W1B to W4B are simply referred to as “wires W.”

As shown in FIG. 18, in the step of placing a submount substrate 80 on the substrate 820, a first conductive bonding material (not shown) is first applied to the element surface electrode 31. The submount substrate 80 is placed on the first conductive bonding material. That is, in this step, the submount substrate 80 is die-bonded to the element surface electrode 31. The first conductive bonding material is a die bonding material, which may be a solder paste or a silver paste, for example.

In the subsequent step of placing an edge-emitting light emitting element 60 on the submount substrate 80, a second conductive bonding material is first applied to the front surface 81 of the submount substrate 80. The edge-emitting light emitting element 60 is then placed on the second conductive bonding material. That is, in this step, the edge-emitting light emitting element 60 is die-bonded to the submount substrate 80. The second conductive bonding material is a die bonding material, which may be a solder paste or a silver paste, for example. The first and second conductive bonding materials may be the same or different. In this manner, the edge-emitting light emitting element 60 is arranged within the frame of the adhesion pattern 33 on the substrate 820. In other words, the adhesion pattern 33 is formed so as to surround the edge-emitting light emitting element 60 in plan view.

In this embodiment, after the edge-emitting light emitting element 60 is placed on the submount substrate 80, the first and second conductive bonding materials are solidified at the same time. More specifically, the first and second conductive bonding materials are solidified by heating and then cooling them. As a result, the first conductive bonding material bonds the element surface electrode 31 and the submount substrate 80, and the second conductive bonding material bonds the submount substrate 80 and the edge-emitting light emitting element 60.

The first and second conductive bonding materials may be solidified separately. In one example, in the step of placing the submount substrate 80 on the substrate 820, the element surface electrode 31 and the submount substrate 80 are bonded by solidifying the first conductive bonding material. Then, in the step of placing the edge-emitting light emitting element 60 on the submount substrate 80, the submount substrate 80 and the edge-emitting light emitting element 60 are bonded by solidifying the second conductive bonding material.

In the subsequent step of forming wires W, wires W are formed so as to individually connect the element electrodes 63 of the edge-emitting light emitting element 60 and the wire connection electrodes 32 using a wire bonding device. The element electrodes 63 are thus electrically connected to the respective wire connection electrodes 32.

As shown in FIG. 19, the method for manufacturing the semiconductor light emitting device 10 includes the steps of applying the adhesive 50 to the adhesion pattern 33, accommodating the edge-emitting light emitting element 60 by placing a cap 70 on the adhesive 50, and bonding the cap 70 to the adhesion pattern 33 by curing the adhesive 50. These steps may be performed after the step of forming wires W, for example.

In the step of applying the adhesive 50 to the adhesion pattern 33, the adhesive 50 is first applied to the entire exposed section of the pattern surface 33S of the adhesion pattern 33 in plan view using a dispenser, for example. That is, the adhesive 50 is not applied to the section of the pattern surface 33S covered with the restriction member 90. The adhesive 50 is also in contact with the outer side surface of the restriction member 90. In this step, the adhesive 50 is applied to the pattern surface 33S of the adhesion pattern 33 such that the thickness dimension TA of the adhesive 50 is less than the thickness dimension TB of the restriction member 90. In one example, the adhesive 50 is a thermosetting adhesive. The type of the adhesive 50 may be modified, and an ultraviolet curing adhesive may be used, for example.

In the subsequent step of accommodating the edge-emitting light emitting element 60 by placing the cap 70 on the adhesive 50, the cap 70 is placed on the adhesive 50 on the adhesion pattern 33. As a result, the restriction member 90 is opposed to the inner side surface 77 of the first to fourth side walls 71 to 74 of the cap 70 in directions perpendicular to the Z-direction.

As shown in FIGS. 20 and 21, in the subsequent step of bonding the cap 70 to the adhesion pattern 33 by curing the adhesive 50, the cap 70 is bonded to the adhesion pattern 33 under load. More specifically, as shown in FIGS. 20 and 21, the upper wall 75 of the cap 70 is pressed toward the substrate 820 by a jig 900. The adhesive 50 is thermally cured in this state.

Although not shown, the method for manufacturing the semiconductor light emitting device 10 includes the subsequent step of cutting the substrate 820 to perform singulation. Substrates 20 are thus formed. The semiconductor light emitting device 10 is manufactured through the above steps.

### Operation

Operation of the semiconductor light emitting device 10 of the first embodiment is now described.

When the cap 70 is bonded to the adhesion pattern 33 by curing the adhesive 50, the gas generated by outgassing of the adhesive 50 and the expansion of the air in the cap 70, which occurs when the adhesive 50 is thermally cured, may lift the cap 70 away from the adhesion pattern 33 in the Z-direction. To limit such lifting of the cap 70, the step of bonding the cap 70 to the adhesion pattern 33 by curing the adhesive 50 performs bonding under load, in which the adhesive 50 is cured with a load applied to the cap 70 toward the adhesion pattern 33 by the jig 900. The jig 900 restricts upward movement of the cap 70.

However, in the bonding under load, movement of the cap 70 in a direction intersecting the Z-direction is not restricted. As such, the cap 70 may move in a direction intersecting the Z-direction when the adhesive 50 is cured.

In this respect, in the first embodiment, the restriction member 90 is in contact with the inner side surface 77 of any of the first to fourth side walls 71 to 74 of the cap 70, thereby restricting movement of the cap 70 in a direction intersecting the Z-direction. This limits displacement of the cap 70 relative to the adhesion pattern 33 in a direction intersecting the Z-direction.

### Advantageous Effects

The semiconductor light emitting device 10 of the first embodiment has the following advantageous effects.

(1-1) The semiconductor light emitting device 10 includes a substrate 20, an edge-emitting light emitting element 60 mounted on the substrate 20, an adhesion pattern 33 that is disposed on the substrate 20 and has a frame shape surrounding the edge-emitting light emitting element 60 in plan view, and a cap 70 accommodating the edge-emitting light emitting element 60. The cap 70 includes first to fourth side walls 71 to 74 opposed to the adhesion pattern 33 in the Z-direction. The first to fourth side walls 71 to 74 have a frame shape and include an opening end surface 76 and an inner side surface 77. The semiconductor light emitting device also includes an adhesive 50 bonding the opening end surface 76 of the first to fourth side walls 71 to 74 to the pattern surface 33S of the adhesion pattern 33, and a restriction member 90 that is disposed on the substrate 20 and is in contact with the inner side surface 77 of the first to fourth side walls 71 to 74 so as to restrict movement of the cap 70 in the Z-direction.

According to this configuration, the restriction member 90 restricts movement of the cap 70 in a direction intersecting the Z-direction in plan view. This limits displacement of the cap 70 relative to the adhesion pattern 33 (substrate 20) when the adhesive 50 is cured.

(1-2) The fourth side wall 74 includes a light transmission surface, which transmits the laser light from the edge-emitting light emitting element 60. The restriction member 90 restricts movement of the cap 70 in a direction intersecting the light transmission surface in plan view.

According to this configuration, the restriction member 90 reduces that possibility that the fourth side wall 74 of the cap 70 moves close to the edge-emitting light emitting element 60 in plan view. Thus, the fourth side wall 74 is unlikely to come into contact with the edge-emitting light emitting element 60 when the adhesive 50 is cured.

(1-3) The restriction member 90 includes a first restriction portion 90A that is positioned so as not to be aligned with the first to fourth side walls 71 to 74 in plan view and is configured to restrict movement of the cap 70 in the X-direction, and a second restriction portion 90B that is positioned so as not to be aligned with the first to fourth side walls 71 to 74 in plan view and is configured to restrict movement of the cap 70 in the Y-direction.

According to this configuration, the first and second restriction portion 90A and 90B restrict movement of the cap 70 in the X and Y-directions. This further limits displacement of the cap 70 relative to the adhesion pattern 33 (substrate 20) when the adhesive 50 is cured.

(1-4) The restriction member 90 has a frame shape surrounding the edge-emitting light emitting element 60 in plan view. The restriction member 90 is disposed along the entire extent in the perimeter direction of the inner side surface 77 of the first to fourth side walls 71 to 74 in plan view.

According to this configuration, the restriction member 90 restricts movement of the cap 70 in all directions intersecting the Z-direction in plan view. Moreover, the frame-shaped restriction member 90 resists deformation when the cap 70 comes into contact with the restriction member 90, as compared with a restriction member including multiple parts spaced apart from each other. This limits displacement of the cap 70 relative to the adhesion pattern 33 (substrate 20) when the adhesive 50 is cured.

(1-5) The restriction member 90 is provided as a resist 890 provided on the adhesion pattern 33.

According to this configuration, the positional accuracy of the restriction member 90 with respect to the adhesion pattern 33 is improved. This further limits displacement of the cap 70 relative to the adhesion pattern 33 (substrate 20) when the adhesive 50 is cured.

(1-6) A method for manufacturing a semiconductor light emitting device 10 includes placing an edge-emitting light emitting element 60 on a substrate 820, applying an adhesive 50 to a pattern surface 33S of an adhesion pattern 33 that surrounds the edge-emitting light emitting element 60 on the substrate 820 in plan view, and accommodating the edge-emitting light emitting element 60 by placing a cap 70 on the adhesive 50. The cap 70 includes first to fourth side walls 71 to 74 opposed to the adhesion pattern 33 in the Z-direction. The first to fourth side walls 71 to 74 have a frame shape and include an opening end surface 76 and an inner side surface 77. The method further includes bonding the cap 70 to the adhesion pattern 33 by curing the adhesive 50. The substrate 820 includes a restriction member 90 that is disposed on the substrate 820 and is in contact with the inner side surface 77 of the first to fourth side walls 71 to 74 so as to restrict movement of the cap 70 in a direction intersecting the Z-direction. The step of bonding the cap 70 to the adhesion pattern 33 includes curing the adhesive 50 with a load applied to the cap 70 toward the adhesion pattern 33.

According to this configuration, since the adhesive 50 is cured with a load applied to the cap 70 toward the adhesion pattern 33, the cap 70 tends to move in a direction intersecting the Z-direction when the adhesive 50 is cured. In this respect, the restriction member 90 restricts movement of the cap 70 in a direction intersecting the Z-direction in plan view. This limits displacement of the cap 70 relative to the adhesion pattern 33 (substrate 20) when the adhesive 50 is cured.

### Modifications of First Embodiment

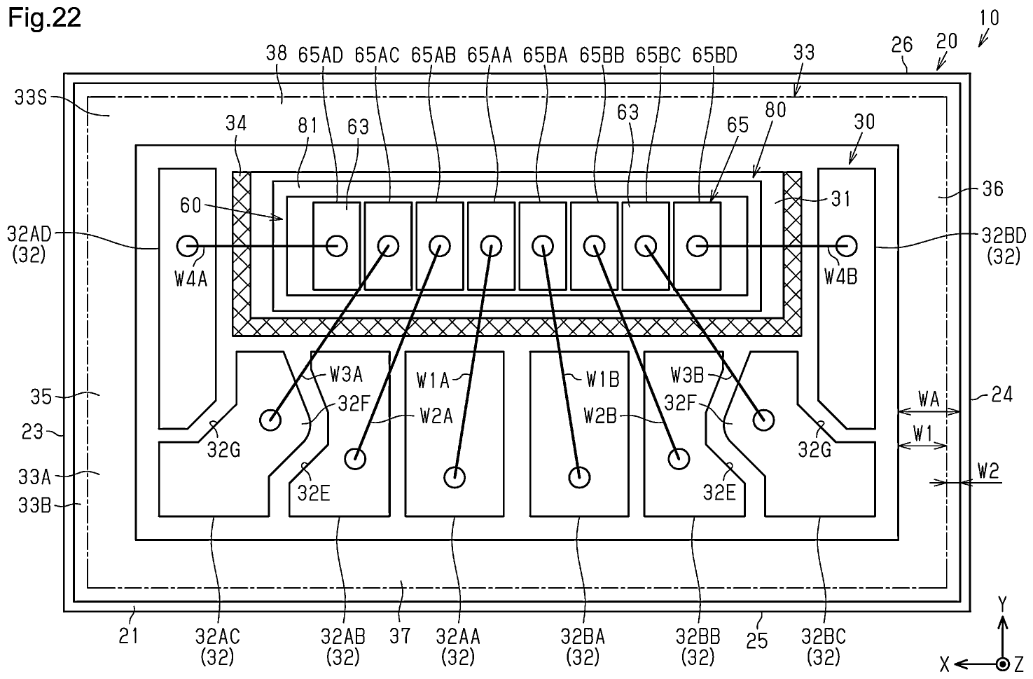

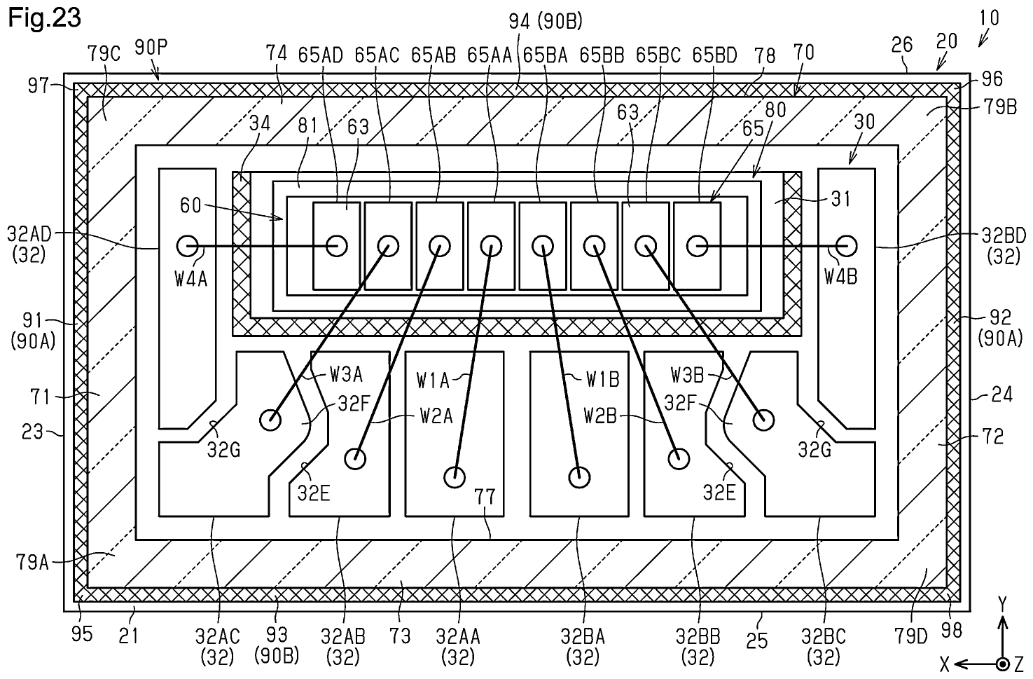

Referring to FIGS. 22 and 23, a modification of the restriction member 90 of the first embodiment is now described. FIG. 22 shows a planar structure of a semiconductor light emitting device 10 with the cap 70 and the restriction member 90P omitted. FIG. 23 shows a planar structure of the semiconductor light emitting device 10 in which the first to fourth side walls 71 to 74 of the cap 70 are cut along an XY plane. The long-dash short-dash line in FIG. 22 indicates the boundary between the first region 33A and the second region 33B of the adhesion pattern 33 for illustrative purposes.

As shown in FIG. 23, the restriction member 90P of the modification may be placed outside the cap 70 in plan view. The components of the semiconductor light emitting device 10 related to the restriction member 90P are described below.

As shown in FIG. 22, the second region 33B of the adhesion pattern 33 is formed at the outer perimeter portion including the outer edge of the adhesion pattern 33. The first region 33A of the adhesion pattern 33 is formed at the inner perimeter portion including the inner edge of the adhesion pattern 33. The relationship between the width dimension W1 of the first region 33A and the width dimension W2 of the second region 33B is the same as that in the first embodiment, for example.

As shown in FIG. 23, the restriction member 90P on the second region 33B is on the outer perimeter portion of the adhesion pattern 33 in plan view. The restriction member 90P therefore has a rectangular frame shape in plan view.

The restriction member 90P includes first to fourth members 91 to 94 and first to fourth corner sections 95 to 98, as in the first embodiment. In the same manner as the first embodiment, the first and second members 91 and 92 of the restriction member 90P form sections of the restriction member 90P extending in the transverse direction. The third and fourth members 93 and 94 form sections of the restriction member 90P extending in the longitudinal direction. The width dimension and the thickness dimension of the first to fourth members 91 to 94 may be the same as those of the restriction member 90 of the first embodiment, for example. The method for manufacturing the restriction member 90P is also the same as that in the first embodiment.

The first to fourth side walls 71 to 74 of the cap 70 are placed on the first region 33A of the adhesion pattern 33. The first to fourth side walls 71 to 74 are therefore arranged in a region different from the second region 33B. That is, in plan view, the restriction member 90P is positioned so as not to be aligned with the first to fourth side walls 71 to 74.

The restriction member 90P having a rectangular frame shape is provided along the entire extent in the perimeter direction of the outer side surface 78 of the first to fourth side walls 71 to 74 in plan view. The restriction member 90P is adjacent to the first to fourth side walls 71 to 74 of the cap 70. More specifically, in plan view, the first member 91 of the restriction member 90P is adjacent to the outer side surface 78 of the first side wall 71 in the X-direction. In plan view, the second member 92 is adjacent to the outer side surface 78 of the second side wall 72 in the X-direction. In plan view, the third member 93 is adjacent to the outer side surface 78 of the third side wall 73 in the Y-direction. In plan view, the fourth member 94 is adjacent to the outer side surface 78 of the fourth side wall 74 in the Y-direction. In plan view, the first corner section 95 of the restriction member 90P is adjacent to the first corner section 79A of the cap 70 in the X and Y-directions. In plan view, the second corner section 96 of the restriction member 90P is adjacent to the second corner section 79B of the cap 70 in the X and Y-directions. In plan view, the third corner section 97 of the restriction member 90P is adjacent to the third corner section 79C of the cap 70 in the X and Y-directions. In plan view, the fourth corner section 98 of the restriction member 90P is adjacent to the fourth corner section 79D of the cap 70 in the X and Y-directions.

According to the configuration of this restriction member 90P, the first and second members 91 and 92 restrict movement of the cap 70 in the X-direction. The third and fourth members 93 and 94 restrict movement of the cap 70 in the Y-direction. As such, it may be considered that the restriction member 90P includes a first restriction portion 90A, which restricts movement of the cap 70 in the X-direction, and a second restriction portion 90B, which restricts movement of the cap 70 in the Y-direction. In this modification, the first and second members 91 and 92 form the first restriction portion 90A. The third and fourth members 93 and 94 form the second restriction portion 90B.

### Second Embodiment

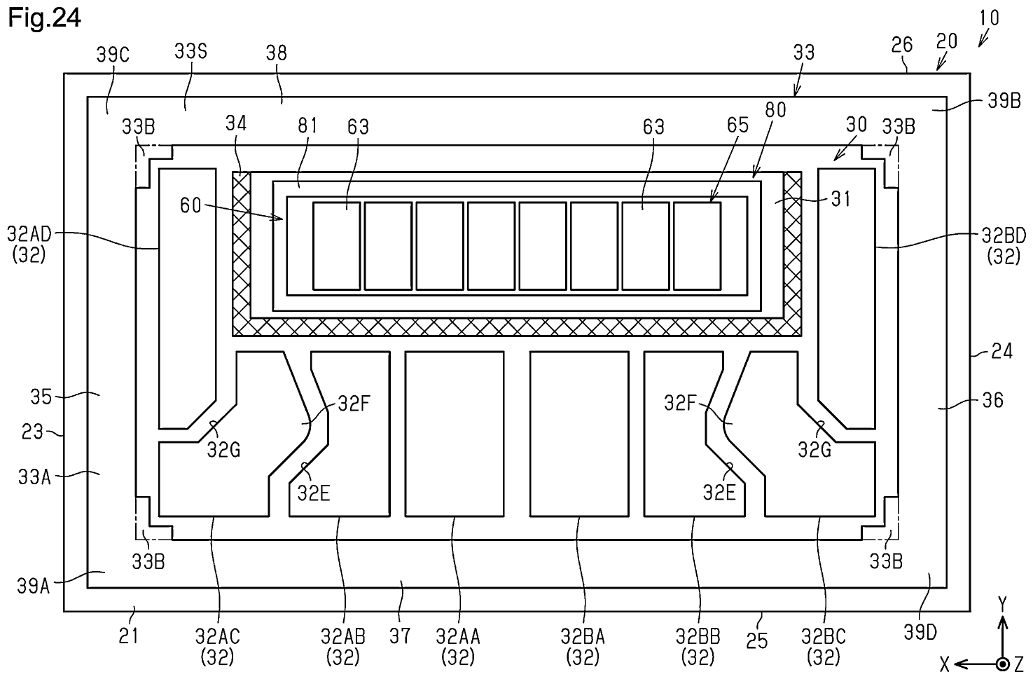

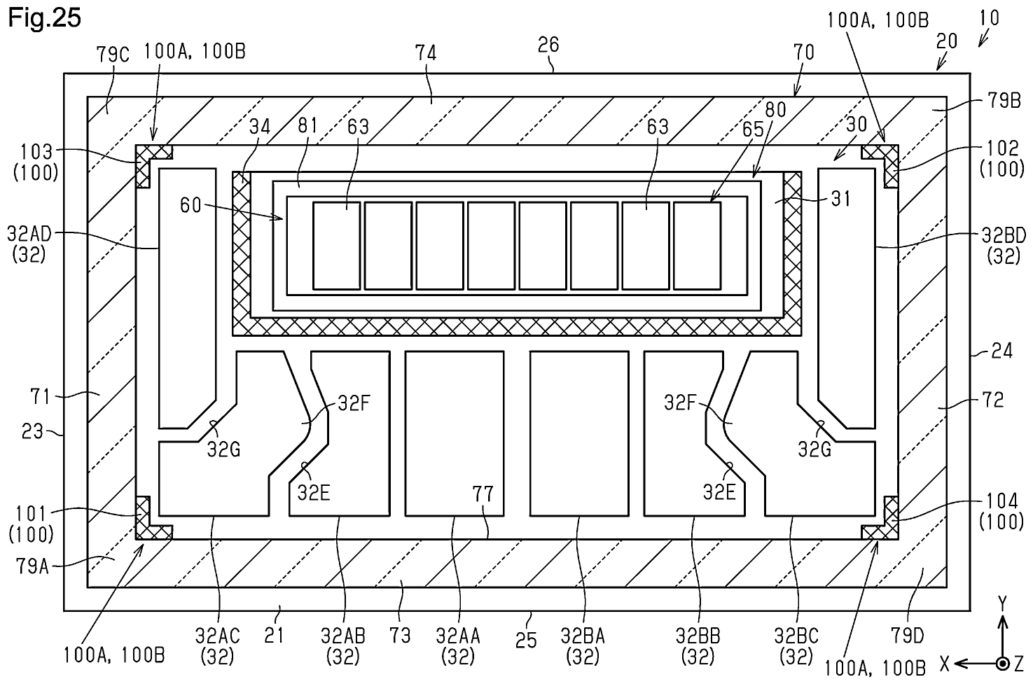

Referring to FIGS. 24 and 25, a second embodiment of a semiconductor light emitting device 10 is now described. The semiconductor light emitting device 10 of the second embodiment differs from the semiconductor light emitting device 10 of the first embodiment in the configuration of the restriction member 100. In the following description, the same reference numerals are given to the same components as in the first embodiment, and the description thereof will be omitted.

FIG. 24 shows a planar structure of the semiconductor light emitting device 10 with the cap 70 and the restriction member 100 omitted. FIG. 25 shows a planar structure of the semiconductor light emitting device 10 in which the first to fourth side walls 71 to 74 of the cap 70 are cut along an XY plane. The long-dash short-dash lines in FIG. 24 indicate the boundaries between the first region 33A and the second regions 33B of the adhesion pattern 33 for illustrative purposes. To facilitate the understanding of the drawings, the wires W1A to W4A and W1B to W4B are omitted in FIGS. 24 and 25.

As shown in FIG. 24, the adhesion pattern 33 includes first to fourth corner sections 39A to 39D. The first corner section 39A is a connection section between the first pattern 35 and the third pattern 37. The second corner section 39B is a connection section between the second pattern 36 and the fourth pattern 38. The third corner section 39C is a connection section between the first pattern 35 and the fourth pattern 38. The fourth corner section 39D is a connection section between the second pattern 36 and the third pattern 37.

In the second embodiment, the adhesion pattern 33 includes second regions 33B formed at the first to fourth corner sections 39A to 39D. As such, the adhesion pattern 33 includes a first region 33A, which has a rectangular frame shape in plan view, and four second regions 33B spaced apart from each other.

In the second embodiment, the four second regions 33B are provided at the inner edge portions of the first to fourth corner sections 39A to 39D. More specifically, the second region 33B in the first corner section 39A is closer to the wire connection electrode 32AC than the first region 33A in the first corner section 39A. The second region 33B in the second corner section 39B is closer to the wire connection electrode 32BD than the first region 33A in the second corner section 39B. The second region 33B in the third corner section 39C is closer to the wire connection electrode 32AD than the first region 33A in the third corner section 39C. The second region 33B in the fourth corner section 39D is closer to the wire connection electrode 32BC than the first region 33A in the fourth corner section 39D.

Each second region 33B is L-shaped in plan view. More specifically, each second region 33B includes a first section extending in the X-direction and a second section extending in the Y-direction. In one example, the length dimension (dimension in the X-direction) of the first section is equal to the length dimension (dimension in the Y-direction) of the second section. In one example, the width dimension (dimension in the Y-direction) of the first section is equal to the width dimension (dimension in the X-direction) of the second section.

The length and width dimensions of the first section and the length and width dimensions of the second section may be modified. In one example, the length dimension of the first section may be greater than the length dimension of the second section. In one example, the width dimension of the first section may be greater than the width dimension of the second section.

As shown in FIG. 25, the restriction member 100 includes four members corresponding to the four second regions 33B (see FIG. 24), namely first to fourth members 101 to 104. As such, it may be considered that the first to fourth members 101 to 104 are spaced apart from each other. Since the cap 70 is placed on the first region 33A (see FIG. 24), the first to fourth members 101 to 104 are positioned so as not to be aligned with the first to fourth side walls 71 to 74 of the cap 70 in plan view.

The first member 101 is provided on the second region 33B in the first corner section 39A of the adhesion pattern 33 (see FIG. 24). As such, the first member 101 is positioned adjacent to the inner side surface 77 of the first corner section 79A of the first to fourth side walls 71 to 74 of the cap 70 in the X and Y-directions.

The second member 102 is provided on the second region 33B in the second corner section 39B of the adhesion pattern 33 (see FIG. 24). As such, the second member 102 is positioned adjacent to the inner side surface 77 of the second corner section 79B of the first to fourth side walls 71 to 74 of the cap 70 in the X and Y-directions. Thus, it may be considered that the first member 101 and the second member 102 are positioned adjacent to the first corner section 79A and the second corner section 79B, which are diagonally opposed, among the first to fourth corner sections 79A to 79D of the first to fourth side walls 71 to 74 in plan view.

The third member 103 is provided on the second region 33B in the third corner section 39C of the adhesion pattern 33 (see FIG. 24). As such, the third member 103 is adjacent to the inner side surface 77 of the third corner section 79C of the first to fourth side walls 71 to 74 of the cap 70 in the X and Y-directions.

The fourth member 104 is provided on the second region 33B in the fourth corner section 39D of the adhesion pattern 33 (see FIG. 24). As such, the fourth member 104 is adjacent to the inner side surface 77 of the fourth corner section 79D of the first to fourth side walls 71 to 74 of the cap 70 in the X and Y-directions. Thus, it may be considered that the third member 103 and the fourth member 104 are positioned adjacent to the third corner section 79C and the fourth corner section 79D, which are diagonally opposed among the first to fourth corner sections 79A to 79D of the first to fourth side walls 71 to 74 in plan view.

The first to fourth members 101 to 104 are L-shaped in plan view, corresponding to the second regions 33B in plan view. As such, in one example, the first to fourth members 101 to 104 have the same shape and size. More specifically, each of the first to fourth members 101 to 104 includes a first section extending in the X-direction and a second section extending in the Y-direction. In one example, the length dimension (dimension in the X-direction) of the first section is equal to the length dimension (dimension in the Y-direction) of the second section. In one example, the width dimension (dimension in the Y-direction) of the first section is equal to the width dimension (dimension in the X-direction) of the second section.

The length and width dimensions of the first section and the length and width dimensions of the second section may be modified. In one example, the length dimension of the first section may be greater than the length dimension of the second section. In one example, the width dimension of the first section may be greater than the width dimension of the second section.

The first section of the first member 101 is opposed to the inner side surface 77 of the third side wall 73 of the cap 70 in the Y-direction. The second section of the first member 101 is opposed to the inner side surface 77 of the first side wall 71 in the X-direction. The first section of the second member 102 is opposed to the inner side surface 77 of the fourth side wall 74 of the cap 70 in the Y-direction. The second section of the second member 102 is opposed to the inner side surface 77 of the second side wall 72 in the X-direction. The first and second members 101 and 102 thus arranged form the first restriction portion 100A, which restricts movement of the cap 70 in the X-direction, and the second restriction portion 100B, which restricts movement of the cap 70 in the Y-direction.

The first section of the third member 103 is opposed to the inner side surface 77 of the fourth side wall 74 of the cap 70 in the Y-direction. The second section of the third member 103 is opposed to the inner side surface 77 of the first side wall 71 of the cap 70 in the X-direction. The first section of the fourth member 104 is opposed to the inner side surface 77 of the third side wall 73 of the cap 70 in the Y-direction. The second section of the fourth member 104 is opposed to the inner side surface 77 of the second side wall 72 of the cap 70 in the X-direction. The third and fourth members 103 and 104 thus arranged form the first restriction portion 100A, which restricts movement of the cap 70 in the X-direction, and the second restriction portion 100B, which restricts movement of the cap 70 in the Y-direction. The semiconductor light emitting device 10 of the second embodiment has the same advantageous effects as the first embodiment.

### Modifications of Second Embodiment

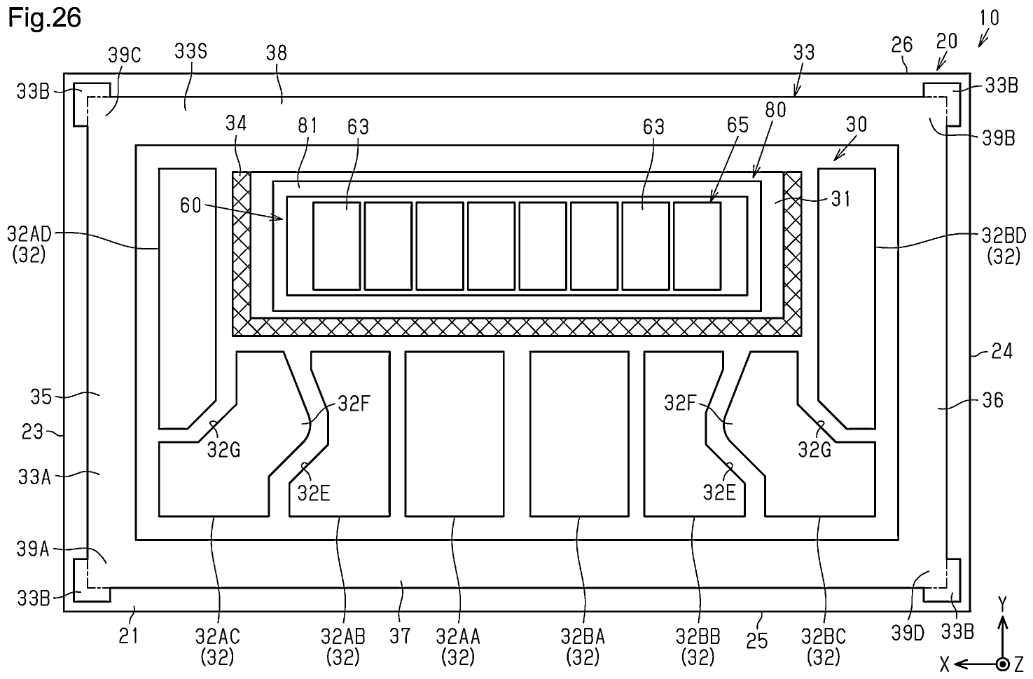

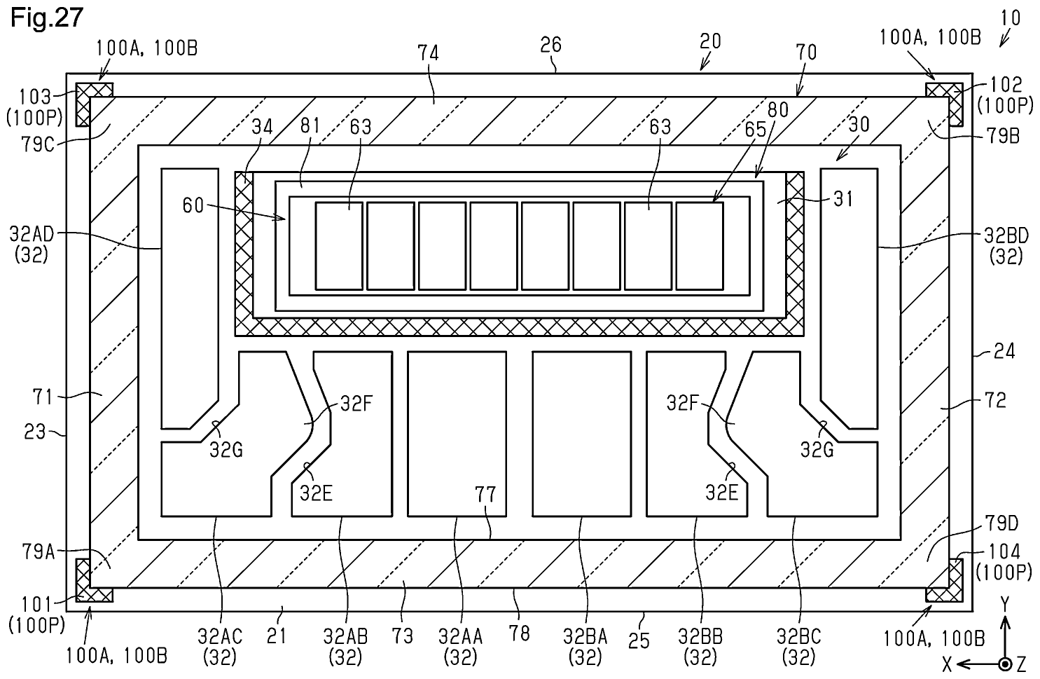

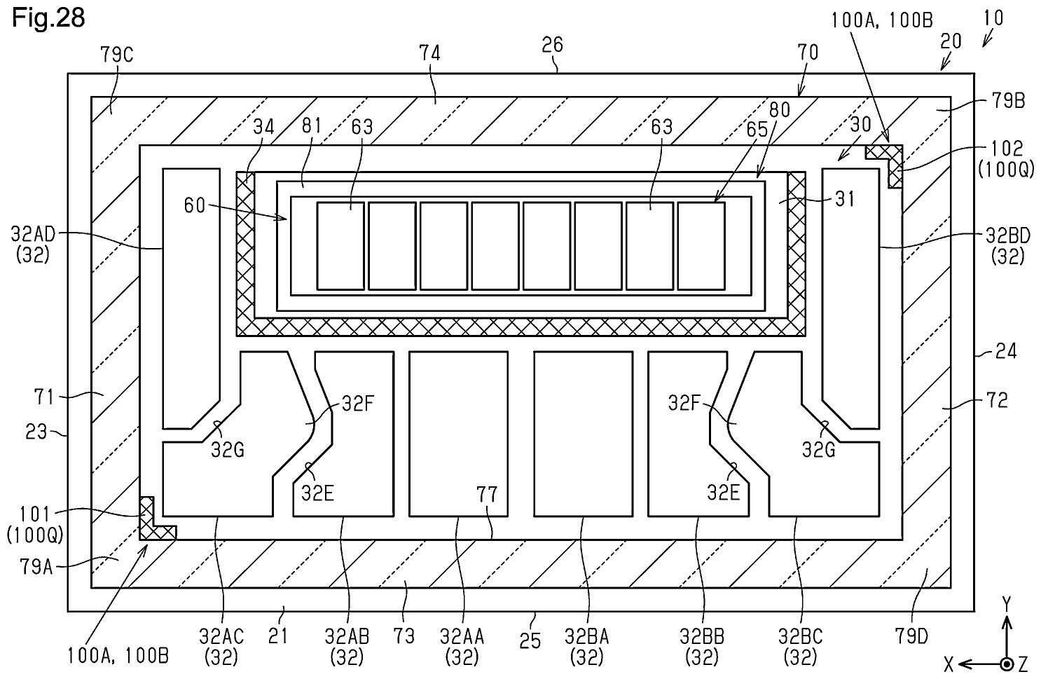

Referring to FIGS. 26 to 28, first and second modifications of the restriction member 100 of the second embodiment are now described. FIG. 26 shows a planar structure of a semiconductor light emitting device 10 of the first modification with the cap 70 and the restriction member 100P omitted. FIG. 27 shows a planar structure of the semiconductor light emitting device 10 of the first modification in which the first to fourth side walls 71 to 74 of the cap 70 are cut along an XY plane. FIG. 28 shows a planar structure of a semiconductor light emitting device 10 of the second modification in which the first to fourth side walls 71 to 74 of the cap 70 are cut along an XY plane. The long-dash short-dash lines in FIG. 26 indicate the boundaries between the first region 33A and the second regions 33B of the adhesion pattern 33 for illustrative purposes. To facilitate the understanding of the drawings, the wires W1A to W4A and W1B to W4B are omitted in FIGS. 26 to 28.

### First Modification

As shown in FIG. 27, the restriction member 100P of the first modification may be placed outside the cap 70 in plan view. The components of the semiconductor light emitting device 10 related to the restriction member 100P are described below.

As shown in FIG. 26, the four second regions 33B of the adhesion pattern 33 are provided in the outer edge portions of the first to fourth corner sections 39A to 39D. More specifically, the second region 33B in the first corner section 39A is closer to the first and third substrate side surfaces 23 and 25 than the first region 33A in the first corner section 39A. The second region 33B in the second corner section 39B is formed closer to the second and fourth substrate side surfaces 24 and 26 than the first region 33A in the second corner section 39B. The second region 33B in the third corner section 39C is closer to the first and fourth substrate side surfaces 23 and 26 than the first region 33A in the third corner section 39C. The second region 33B in the fourth corner section 39D is closer to the second and third substrate side surfaces 24 and 25 than the first region 33A in the fourth corner section 39D.

Each second region 33B is L-shaped in plan view. More specifically, each second region 33B includes a first section extending in the X-direction and a second section extending in the Y-direction. In one example, the length dimension (dimension in the X-direction) of the first section is equal to the length dimension (dimension in the Y-direction) of the second section. In one example, the width dimension (dimension in the Y-direction) of the first section is equal to the width dimension (dimension in the X-direction) of the second section.

The length and width dimensions of the first section and the length and width dimensions of the second section may be modified. In one example, the length dimension of the first section may be greater than the length dimension of the second section. In one example, the width dimension of the first section may be greater than the width dimension of the second section.

As shown in FIG. 27, the restriction members 100P provided on the four second regions 33B (see FIG. 26) are at the outer perimeter portion of the adhesion pattern 33 (see FIG. 26) in plan view. The first to fourth side walls 71 to 74 of the cap 70 are placed on the first region 33A of the adhesion pattern 33 (see FIG. 26). The first to fourth side walls 71 to 74 are therefore arranged in a region different from the second regions 33B. That is, in plan view, the restriction member 100P is positioned so as not to be aligned with the first to fourth side walls 71 to 74.

The first member 101 is adjacent to the outer side surface 78 of the first corner section 79A of the first to fourth side walls 71 to 74 of the cap 70 in the X and Y-directions. The second member 102 is adjacent to the outer side surface 78 of the second corner section 79B of the first to fourth side walls 71 to 74 of the cap 70 in the X and Y-directions. Thus, it may be considered that the first member 101 and the second member 102 are positioned adjacent to the first corner section 79A and the second corner section 79B, which are diagonally opposed among the first to fourth corner sections 79A to 79D of the first to fourth side walls 71 to 74.

The third member 103 is adjacent to the outer side surface 78 of the third corner section 79C of the first to fourth side walls 71 to 74 of the cap 70 in the X and Y-directions. The fourth member 104 is adjacent to the outer side surface 78 of the fourth corner section 79D of the first to fourth side walls 71 to 74 of the cap 70 in the X and Y-directions. Thus, it may be considered that the third member 103 and the fourth member 104 are positioned adjacent to the third corner section 79C and the fourth corner section 79D, which are diagonally opposed among the first to fourth corner sections 79A to 79D of the first to fourth side walls 71 to 74 in plan view.

The first to fourth members 101 to 104 are L-shaped in plan view, corresponding to the second regions 33B in plan view. As such, in one example, the first to fourth members 101 to 104 have the same shape and size. More specifically, each of the first to fourth members 101 to 104 includes a first section extending in the X-direction and a second section extending in the Y-direction. In one example, the length dimension (dimension in the X-direction) of the first section is equal to the length dimension (dimension in the Y-direction) of the second section. In one example, the width dimension (dimension in the Y-direction) of the first section is equal to the width dimension (dimension in the X-direction) of the second section.

The length and width dimensions of the first section and the length and width dimensions of the second section may be modified. In one example, the length dimension of the first section may be greater than the length dimension of the second section. In one example, the width dimension of the first section may be greater than the width dimension of the second section.

The first section of the first member 101 is opposed to the outer side surface 78 of the third side wall 73 of the cap 70 in the Y-direction. The second section of the first member 101 is opposed to the outer side surface 78 of the first side wall 71 in the X-direction. The first section of the second member 102 is opposed to the outer side surface 78 of the fourth side wall 74 of the cap 70 in the Y-direction. The second section of the second member 102 is opposed to the outer side surface 78 of the second side wall 72 in the X-direction. The first and second members 101 and 102 thus arranged form the first restriction portion 100A, which restricts movement of the cap 70 in the X-direction, and the second restriction portion 100B, which restricts movement of the cap 70 in the Y-direction.

The first section of the third member 103 is opposed to the outer side surface 78 of the fourth side wall 74 of the cap 70 in the Y-direction. The second section of the third member 103 is opposed to the outer side surface 78 of the first side wall 71 of the cap 70 in the X-direction. The first section of the fourth member 104 is opposed to the outer side surface 78 of the third side wall 73 of the cap 70 in the Y-direction. The second section of the fourth member 104 is opposed to the outer side surface 78 of the second side wall 72 of the cap 70 in the X-direction. The third and fourth members 103 and 104 thus arranged form the first restriction portion 100A, which restricts movement of the cap 70 in the X-direction, and the second restriction portion 100B, which restricts movement of the cap 70 in the Y-direction.

### Second Modification

As shown in FIG. 28, the restriction member 100Q of the second modification includes fewer restriction members than the restriction member 100 of the second embodiment. In the example shown in FIG. 28, the restriction member 100Q includes a first member 101 and a second member 102. That is, the restriction member 100Q does not include a third member 103 or a fourth member 104 (see FIG. 25). The first and second members 101 and 102 alone can still form the first and second restriction portions 100A and 100B, thereby restricting movement of the cap 70 in the X and Y-directions. The restriction member 100Q of the second modification may have a configuration that includes third and fourth members 103 and 104 and do not include first and second members 101 and 102. Also, the first and second members 101 and 102 may be placed outside the cap 70 so as to be opposed to the outer side surface 78 of the cap 70, as in the first modification shown in FIG. 27.

### Third Embodiment

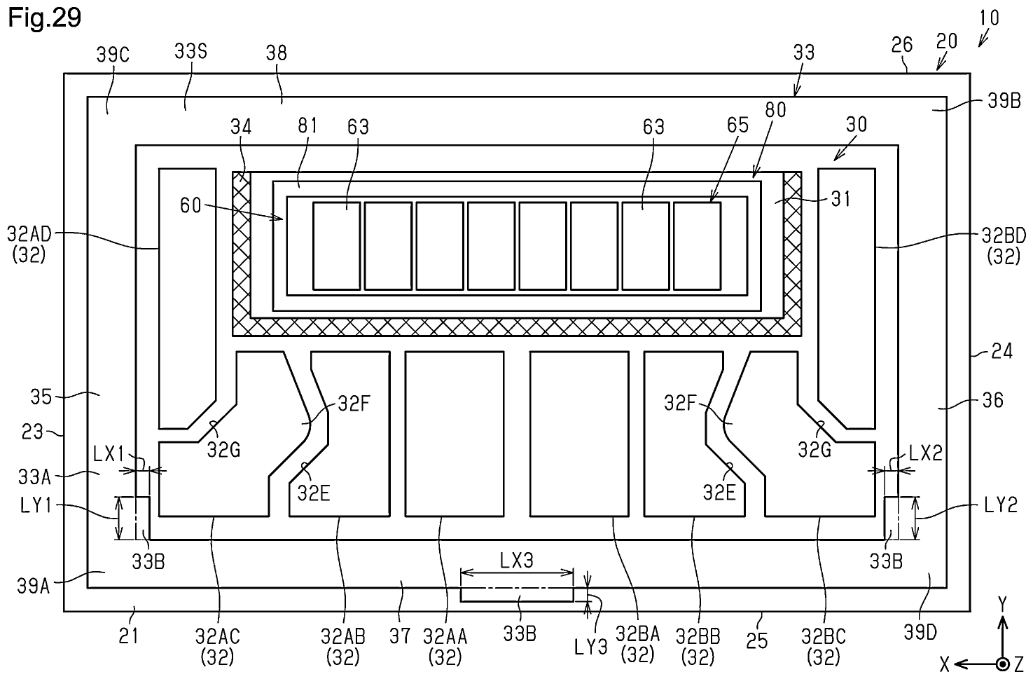

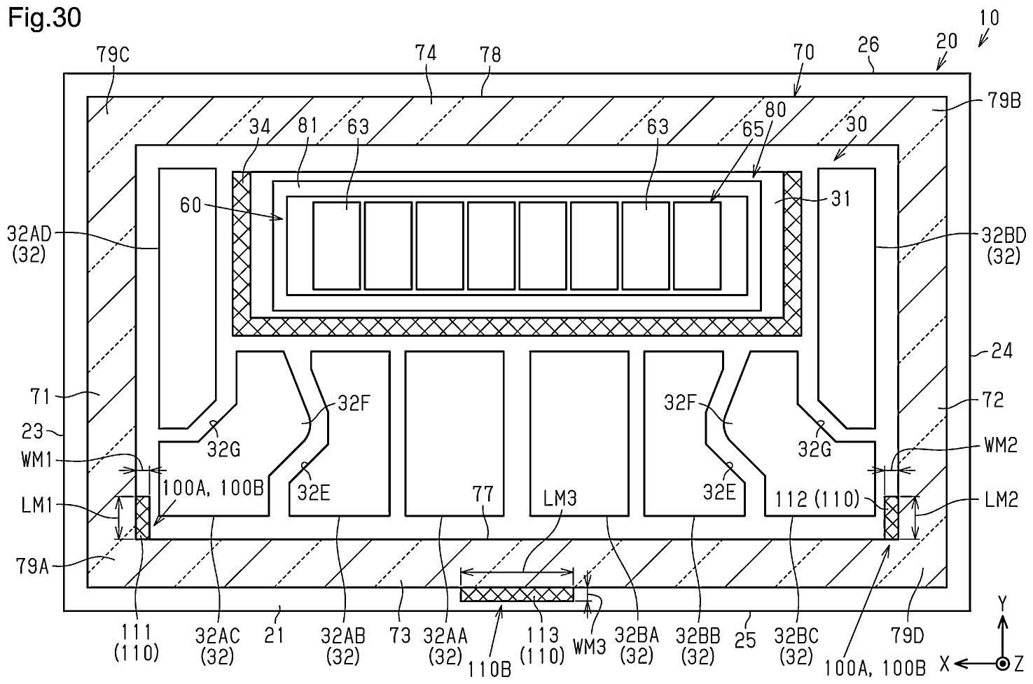

Referring to FIGS. 29 and 30, a third embodiment of a semiconductor light emitting device 10 is now described. The semiconductor light emitting device 10 of the third embodiment differs from the semiconductor light emitting device 10 of the first embodiment in the configuration of the restriction member 110. In the following description, the same reference numerals are given to the same components as in the first embodiment, and the description thereof will be omitted.

FIG. 29 shows a planar structure of the semiconductor light emitting device 10 with the cap 70 and the restriction member 110 omitted. FIG. 30 shows a planar structure of the semiconductor light emitting device 10 in which the first to fourth side walls 71 to 74 of the cap 70 are cut along an XY plane. The long-dash short-dash lines in FIG. 29 indicate the boundaries between the first region 33A and the second regions 33B of the adhesion pattern 33 for illustrative purposes. To facilitate the understanding of the drawings, the wires W1A to W4A and W1B to W4B are omitted in FIGS. 26 to 28.

As shown in FIG. 29, in the third embodiment, the second regions 33B are formed in the first corner section 39A of the adhesion pattern 33, the fourth corner section 39D, and the center section in the X-direction of the third pattern 37. The first region 33A of the adhesion pattern 33 has a rectangular frame shape in the same manner as the first region 33A of the second embodiment.

The second region 33B in the first corner section 39A and the second region 33B in the fourth corner section 39D are in a strip shape extending in the Y-direction in plan view. As such, with the second region 33B in the first corner section 39A, the length dimension LY1 of the section connected to the first pattern 35 (the length of the second region 33B in the Y-direction) is greater than the length dimension LX1 of the section connected to the third pattern 37 (the length of the second region 33B in the X-direction). With the second region 33B in the fourth corner section 39D, the length dimension LY2 of the section connected to the second pattern 36 (the length of the second region 33B in the Y-direction) is greater than the length dimension LX2 of the section connected to the third pattern 37 (the length of the second region 33B in the X-direction). In one example, the second region 33B in the first corner section 39A and the second region 33B in the fourth corner section 39D have the same shape and size. The shapes and sizes of the second region 33B in the first corner section 39A and the second region 33B in the fourth corner section 39D may be modified.

The second region 33B in the center section in the X-direction of the third pattern 37 extends in the X-direction. In one example, the length dimension LX3 of the second region 33B in the center section in the X-direction of the third pattern 37 is greater than the length dimension LY1 of the second region 33B in the first corner section 39A and the length dimension LY2 of the second region 33B in the fourth corner section 39D. The length dimension LY3 of the second region 33B in the center section in the X-direction of the third pattern 37 (the length of the second region 33B in the Y-direction) may be equal to the length dimension LX1 of the second region 33B in the first corner section 39A and the length dimension LX2 of the second region 33B in the fourth corner section 39D, for example.

The length dimension LY3 and the length dimension LX3 of the second region 33B in the center section in the X-direction of the third pattern 37 may be modified. In one example, the length dimension LY3 may be greater than length dimensions LX1 and LX2.

As shown in FIG. 30, the restriction member 110 includes three members corresponding to the three second regions 33B (see FIG. 29), namely first to third members 111 to 113. As such, it may be considered that the first to third members 111 to 113 are spaced apart from each other. Since the cap 70 is placed on the first region 33A, the first to third members 111 to 113 are positioned so as not to be aligned with the first to fourth side walls 71 to 74 of the cap 70 in plan view.

The first member 111 is provided on the second region 33B in the first corner section 39A of the adhesion pattern 33 (see FIG. 29). As such, the first member 111 is adjacent to the inner side surface 77 of the first corner section 79A of the first to fourth side walls 71 to 74 of the cap 70 in the X and Y-directions.

The second member 112 is provided on the second region 33B in the fourth corner section 39D of the adhesion pattern 33 (see FIG. 29). As such, the second member 112 is adjacent to the inner side surface 77 of the fourth corner section 79D of the first to fourth side walls 71 to 74 of the cap 70 in the X and Y-directions.

The third member 113 is provided on the second region 33B in the center section in the X-direction of the third pattern 37 of the adhesion pattern 33 (see FIG. 29). As such, the third member 113 is adjacent to the outer side surface 78 of the third side wall 73 of the first to fourth side walls 71 to 74 of the cap 70 in the Y-direction.

The first to third members 111 to 113 have shapes that correspond to the shapes of the respective second regions 33B in plan view. That is, in plan view, the first member 111 and the second member 112 are in a strip shape extending in the Y-direction. In plan view, the third member 113 is formed in a strip shape extending in the X-direction. In one example, the length dimension LM3 of the third member 113 is greater than the length dimension LM1 of the first member 111 and the length dimension LM2 of the second member 112. In one example, the length dimension LM1 of the first member 111 is equal to the length dimension LM2 of the second member 112. In one example, the width dimension WM3 of the third member 113 is equal to the width dimension WM1 of the first member 111 and the width dimension WM2 of the second member 112.

The length dimension LM3 of the third member 113 is defined by the dimension of the third member 113 in the X-direction. The width dimension WM3 of the third member 113 is defined by the dimension of the third member 113 in the Y-direction. The length dimension LM1 of the first member 111 is defined by the dimension of the first member 111 in the Y-direction. The width dimension WM1 of the first member 111 is defined by the dimension of the first member 111 in the X-direction. The length dimension LM2 of the second member 112 is defined by the dimension of the second member 112 in the Y-direction. The width dimension WM2 of the second member 112 is defined by the dimension of the second member 112 in the X-direction. The length dimensions LM1 to LM3 and the width dimensions WM1 to WM3 of the first to third members 111 to 113 may be modified.

The first member 111 is opposed to the inner side surface 77 of the first side wall 71 of the cap 70 in the X-direction, and is also opposed to the inner side surface 77 of the third side wall 73 in the Y-direction. The second member 112 is opposed to the inner side surface 77 of the second side wall 72 of the cap 70 in the X-direction, and is also opposed to the inner side surface 77 of the third side wall 73 in the Y-direction. The first and second members 111 and 112 thus arranged form the first restriction portion 110A, which restricts movement of the cap 70 in the X-direction.

The third member 113 is opposed to the outer side surface 78 of the third side wall 73 of the cap 70 in the Y-direction. That is, the third side wall 73 is interposed between the first member 111, the second member 112, and the third member 113 in the Y-direction. The first to third members 111 to 113 thus arranged form the second restriction portion 110B, which restricts movement of the cap 70 in the Y-direction.

### Advantageous Effects

The semiconductor light emitting device 10 of the third embodiment has the following advantageous effects.

(3-1) The restriction member 110 includes the first member 111 adjacent to the inner side surface 77 of the first corner section 79A of the cap 70, the second member 112 adjacent to the inner side surface 77 of the fourth corner section 79D, and the third member 113 adjacent to the outer side surface 78 of the third side wall 73 at a position adjacent to the third side wall 73 in the Y-direction. The first to fourth side walls 71 to 74 have a rectangular frame shape having a longitudinal direction in the X-direction and a transverse direction in the Y-direction in plan view. The length dimension LM3 of the third member 113 is greater than the length dimension LM1 of the first member 111 and the length dimension LM2 of the second member 112.

According to this configuration, an increased length dimension LM3 of the third member 113, which restricts movement of the third side wall 73 extending in the longitudinal direction among the first to fourth side walls 71 to 74, further facilitates the restriction of movement of the cap 70 in the Y-direction.

### Modifications

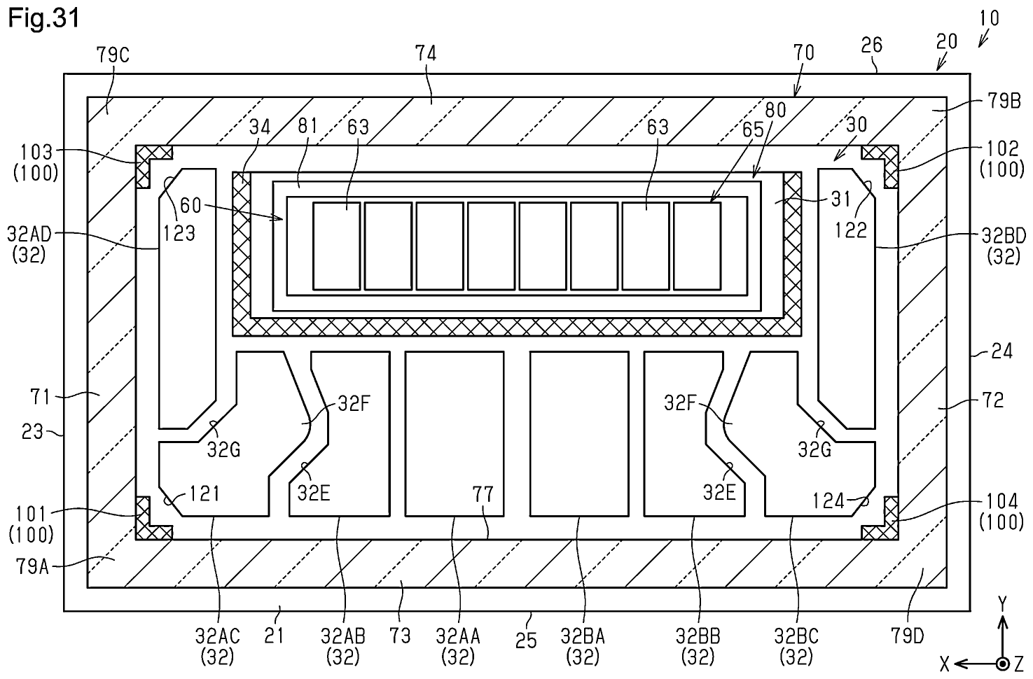

The embodiments described above may be modified as follows. The above modifications may be combined to an extent that does not cause technical contradiction. To facilitate the understanding of the drawings, the wires W1A to W4A and W1B to W4B are omitted in FIGS. 31 to 33 and 35.

In the first embodiment, the restriction member 90 does not need to have a rectangular frame shape. In one example, the fourth member 94 may be omitted from the restriction member 90. That is, the restriction member 90 may be formed by the first to third members 91 to 93.

In the first embodiment, the restriction member 90 may be formed by the first member 91 and the second member 92. That is, the third and fourth members 93 and 94 may be omitted from the restriction member 90. In this case, one of the end portions in the Y-direction of each of the first member 91 and the second member 92 is in contact with the inner side surface 77 of the third side wall 73 or the inner side surface 77 of the fourth side wall 74 of the cap 70 to restrict movement of the cap 70 in the Y-direction. In this manner, the first and second members 91 and 92 form the first restriction portion 90A and the second restriction portion 90B.

In the first embodiment, the restriction member 90 may be formed by the third and fourth members 93 and 94. That is, the first and second members 91 and 92 may be omitted from the restriction member 90. In this case, one of the ends of the third member 93 and the fourth member 94 in the X-direction is in contact with the inner side surface 77 of the first side wall 71 or the inner side surface 77 of the second side wall 72 of the cap 70 to restrict movement of the cap 70 in the X-direction. In this manner, the third and fourth members 93 and 94 form the first restriction portion 90A and the second restriction portion 90B.

In the second embodiment, the shapes of the wire connection electrodes 32AC, 32AD, 32BC, and 32BD may be modified. In one example, as shown in FIG. 31, the wire connection electrode 32AC includes a cutout section 121 cut out in a direction intersecting the Z-direction in plan view. The cutout section 121 is formed at the end portion of the wire connection electrode 32AC near the first member 101 of the restriction member 100. The cutout section 121 is formed to be spaced apart from the first member 101 in plan view. In one example, the cutout section 121 is an inclined surface that is inclined toward the third substrate side surface 25 in a direction from the first substrate side surface 23 toward the second substrate side surface 24.

The wire connection electrode 32BD includes a cutout section 122 cut out in a direction intersecting the Z-direction in plan view. The cutout section 122 is formed at the end portion of the wire connection electrode 32BD near the second member 102. The cutout section 122 is formed to be spaced apart from the second member 102 in plan view. In one example, the cutout section 122 is an inclined surface that is inclined toward the third substrate side surface 25 in a direction from the first substrate side surface 23 toward the second substrate side surface 24.

The wire connection electrode 32AD includes a cutout section 123 cut out in a direction intersecting the Z-direction in plan view. The cutout section 123 is formed at the end portion of the wire connection electrode 32AD near the third member 103. The cutout section 123 is formed to be spaced apart from the third member 103 in plan view. In one example, the cutout section 123 is an inclined surface that is inclined toward the fourth substrate side surface 26 in a direction from the first substrate side surface 23 toward the second substrate side surface 24.

The wire connection electrode 32BC includes a cutout section 124 cut out in a direction intersecting the Z-direction in plan view. The cutout section 124 is formed at the end portion of the wire connection electrode 32BC near the fourth member 104. The cutout section 124 is formed to be spaced apart from the fourth member 104 in plan view. In one example, the cutout section 124 is an inclined surface that is inclined toward the fourth substrate side surface 26 in a direction from the first substrate side surface 23 toward the second substrate side surface 24.

The cutout sections 121 to 124 increase the distances between the adhesion pattern 33 and the wire connection electrodes 32AC, 32AD, 32BC, and 32BD in plan view. This reduces the possibility that the first to fourth members 101 to 104 electrically connect the adhesion pattern 33 to the wire connection electrodes 32AC, 32AD, 32BC, and 32BD.

In the second embodiment, the first and third members 101 and 103 of the restriction member 100 may be connected to each other in the Y-direction. That is, the second section of the first member 101 may be connected to the second section of the third member 103. In this case, the first and third members 101 and 103 are opposed, in the X-direction, to the entire extent in the Y-direction of the inner side surface 77 of the first side wall 71 of the cap 70 in plan view.

In the second embodiment, the second member 102 and the fourth member 104 of the restriction member 100 may be connected to each other in the Y-direction. That is, the second section of the second member 102 may be connected to the second section of the fourth member 104. In this case, the second and fourth members 102 and 104 are opposed, in the X-direction, to the entire extent in the Y-direction of the inner side surface 77 of the second side wall 72 of the cap 70 in plan view.

In the second embodiment, the first and fourth members 101 and 104 of the restriction member 100 may be connected to each other in the X-direction. That is, the first section of the second member 101 may be connected to the first section of the fourth member 104. In this case, the first and fourth members 101 and 104 are opposed, in the Y-direction, to the entire extent in the X-direction of the inner side surface 77 of the third side wall 73 of the cap 70 in plan view.

In the second embodiment, the second and third members 102 and 103 of the restriction member 100 may be connected to each other in the X-direction. That is, the first section of the second member 102 may be connected to the first section of the third member 103. In this case, the second and third members 102 and 103 are opposed, in the Y-direction, to the entire extent in the X-direction of the inner side surface 77 of the fourth side wall 74 of the cap 70 in plan view.

In the second embodiment, the first to fourth members 101 to 104 are L-shaped in plan view, but there is no limitation to this. For example, the first to fourth members 101 to 104 may have a configuration in which the first and second sections are spaced apart from each other.

In the third embodiment, the shapes of the first and second members 111 and 112 of the restriction member 110 in plan view may be modified. In one example, at least one of the first and second members 111 and 112 may be L-shaped in plan view. When the first member 111 is L-shaped, the first member 111 includes a first section extending in the Y-direction and a second section extending in the X-direction. The first section is adjacent to the inner side surface 77 of the first side wall 71 of the cap 70 in the X-direction in plan view. The second section is adjacent to the inner side surface 77 of the third side wall 73 in the Y-direction in plan view. When the second member 112 is L-shaped, the second member 112 includes a first section extending in the Y-direction and a second section extending in the X-direction. The first section is adjacent to the inner side surface 77 of the second side wall 72 in the X-direction in plan view. The second section is adjacent to the inner side surface 77 of the third side wall 73 in the Y-direction in plan view.

In the third embodiment, the first and second members 111 and 112 of the restriction member 110 may be connected to each other. That is, the second section of the first member 111 may be connected to the second section of the second member 112. In this case, the first and second members 111 and 112 are opposed, in the Y-direction, to the entire extent in the X-direction of the inner side surface 77 of the third side wall 73 of the cap 70 in plan view.

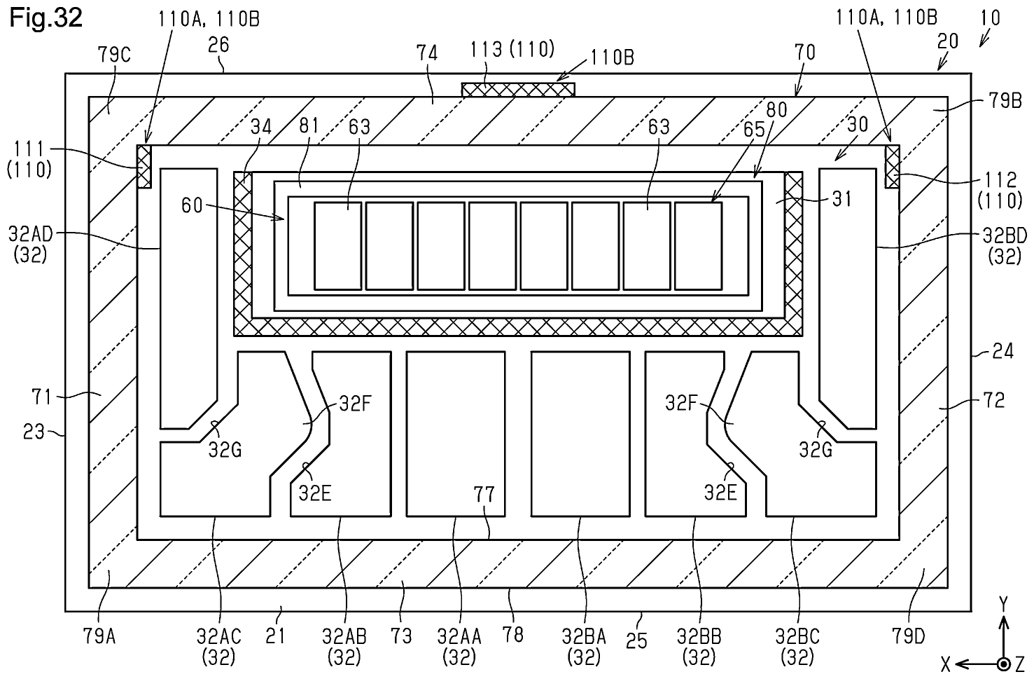

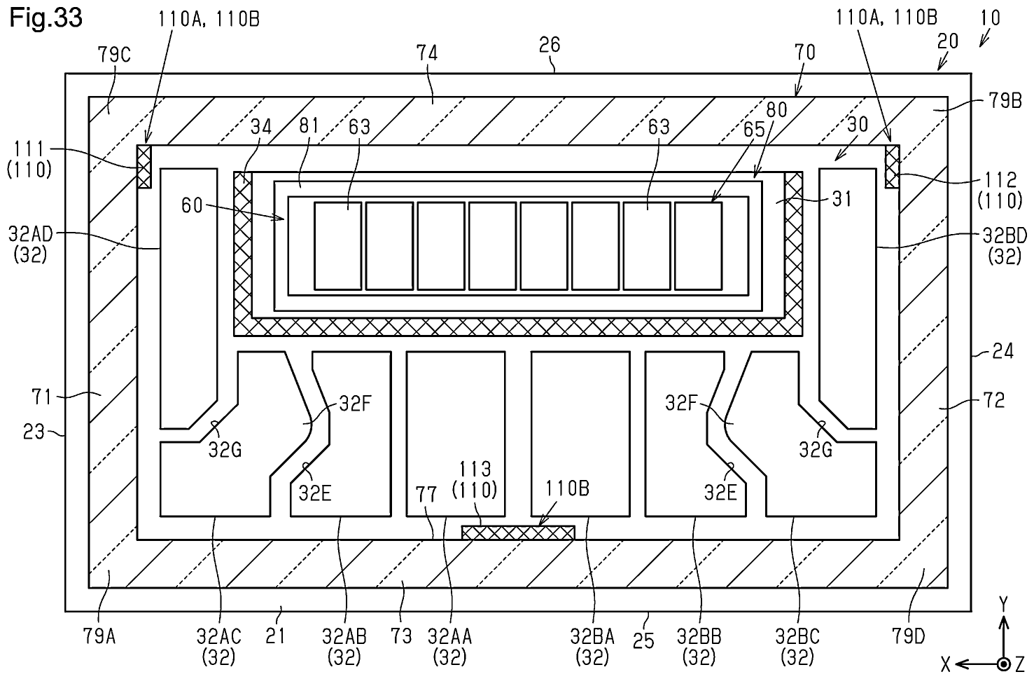

In the third embodiment, the arrangement of the first to third members 111 to 113 of the restriction member 110 may be modified. The arrangement of the first to third members 111 to 113 may be modified as in the first modification shown in FIG. 32 and the second modification shown in FIG. 33, for example.

As shown in FIG. 32, in the first modification, the first member 111 of the restriction member 110 is adjacent to the inner side surface 77 of the third corner section 79C of the cap 70 in the X and Y-directions in plan view. The second member 112 is adjacent to the inner side surface 77 of the second corner section 79B of the cap 70 in the X and Y-directions in plan view. The third member 113 is adjacent to the outer side surface 78 of the fourth side wall 74 of the cap 70 in the Y-direction in plan view.

The first member 111 is opposed to the inner side surface 77 of the first side wall 71 of the cap 70 in the X-direction, and is also opposed to the inner side surface 77 of the fourth side wall 74 in the Y-direction. The second member 112 is opposed to the inner side surface 77 of the second side wall 72 of the cap 70 in the X-direction, and is also opposed to the inner side surface 77 of the fourth side wall 74 in the Y-direction. The first and second members 111 and 112 thus arranged form the first restriction portion 110A, which restricts movement of the cap 70 in the X-direction.

The third member 113 is opposed to the outer side surface 78 of the fourth side wall 74 of the cap 70 in the Y-direction. That is, the fourth side wall 74 is interposed between the first member 111, the second member 112, and the third member 113 in the Y-direction. The first to third members 111 to 113 thus arranged form the second restriction portion 110B, which restricts movement of the cap 70 in the Y-direction. Although not shown, in accordance with the modification of the arrangement of the first to third members 111 to 113, the arrangement positions of the three second regions 33B of the adhesion pattern 33 are also modified.

As shown in FIG. 33, in the second modification, the first member 111 of the restriction member 110 is adjacent to the inner side surface 77 of the third corner section 79C of the cap 70 in the X and Y-directions in plan view. The second member 112 is adjacent to the inner side surface 77 of the second corner section 79B of the cap 70 in the X and Y-directions in plan view. The third member 113 is adjacent to the inner side surface 77 of the third side wall 73 in the Y-direction in plan view.

The shapes of the first and second members 111 and 112 in plan view are the same as the first and second members 111 and 112 in the first modification of FIG. 32. The first and second members 111 and 112 thus arranged form the first restriction portion 110A, which restricts movement of the cap 70 in the X-direction.

The third member 113 is opposed to the inner side surface 77 of the third side wall 73 of the cap 70 in the Y-direction. The first to third members 111 to 113 thus arranged form the second restriction portion 110B, which restricts movement of the cap 70 in the Y-direction.

According to the restriction member 110 of the second modification shown in FIG. 33, the first to third members 111 to 113 are accommodated in the cap 70. This improves the appearance of the semiconductor light emitting device 10.

In the third embodiment, at least one of the first and second members 111 and 112 may be omitted from the restriction member 110. For example, when both the first and second members 111 and 112 are omitted from the restriction member 110, the third member 113 restricts movement of the cap 70 toward the third substrate side surface 25 in plan view. This limits contact between the fourth side wall 74 of the cap 70 and the edge-emitting light emitting element 60.

In each embodiment, the restriction members 90, 100, and 110 are provided on the adhesion patterns 33, but there is no limitation to this. The configurations of the restriction members 90, 100, and 110 may be modified as in the following first modification and second modification.

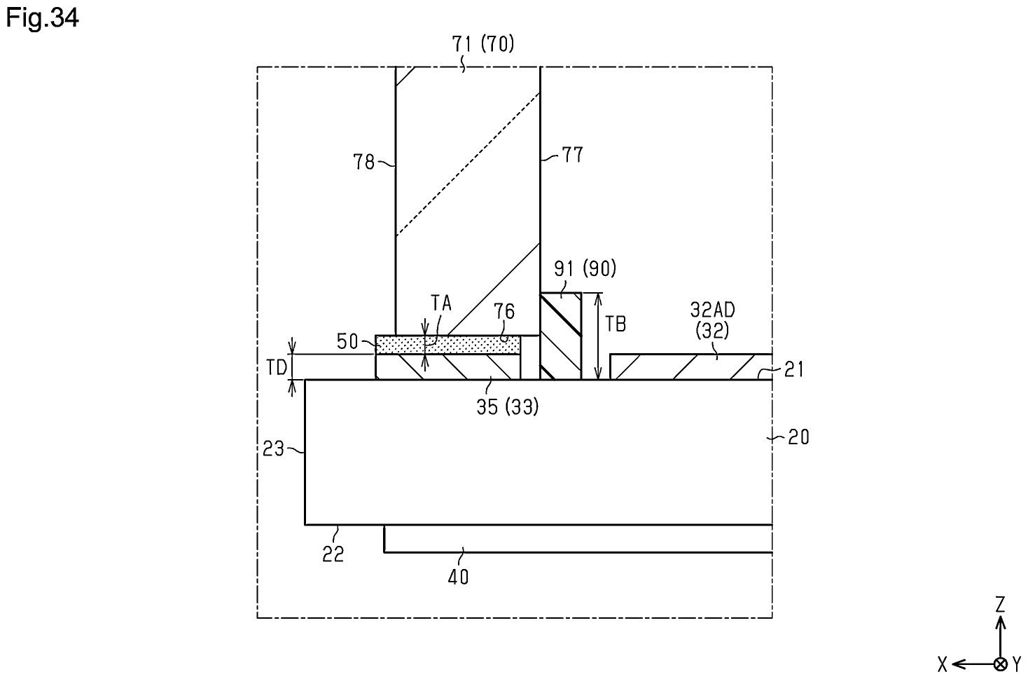

In the first modification, the restriction member 90 may be provided separately from the adhesion pattern 33. That is, the restriction member 90 may be spaced apart from the adhesion pattern 33 in plan view. In one example, as shown in FIG. 34, the restriction member 90 is in contact with the substrate surface 21 of the substrate 20. That is, the restriction member 90 is provided on the substrate surface 21 of the substrate 20. In the example shown in FIG. 34, the restriction member 90 is placed between the adhesion pattern 33 and the wire connection electrode 32AD in the X-direction. The restriction member 90 is spaced apart from both the adhesion pattern 33 and the wire connection electrode 32AD in the X-direction. In other words, the restriction member 90 is spaced apart from both the adhesion pattern 33 and the surface electrode 30. The thickness dimension TB of the restriction member 90 is greater than the sum of the thickness dimension TD of the adhesion pattern 33 and the thickness dimension TA of the adhesive 50. Thus, the restriction member 90 is opposed to the inner side surface 77 of the first to fourth side walls 71 to 74 of the cap 70.

The restriction member 90 of the first modification may be made of an insulating material, for example. The insulating material may be epoxy resin. Also, the restriction member 90 of the first modification may be made of a metal material. In this case, the restriction member 90 may be made of the same material as the adhesion pattern 33, for example. The restriction member 90 may also be made of the same material as the surface electrodes 30, for example.

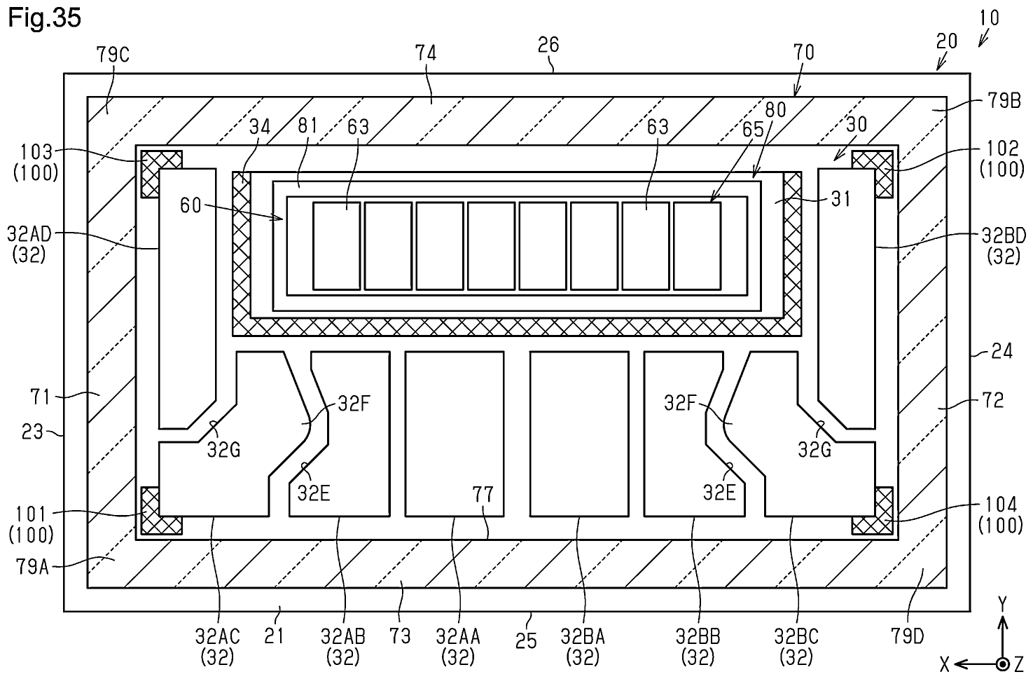

In the second modification, the restriction member 100 may be provided on surface electrodes 30. In one example, as shown in FIG. 35, the first member 101 is provided on the wire connection electrode 32AC. The second member 102 is provided on the wire connection electrode 32BD. The third member 103 is provided on the wire connection electrode 32AD. The fourth member 104 is provided on the wire connection electrode 32BC.

The restriction member 100 may be provided on at least one of the adhesion pattern 33 or a surface electrode 30. In one example, the first member 101 is provided on the wire connection electrode 32AC, and the second member 102 is provided on the wire connection electrode 32BD. The third and fourth members 103 and 104 are provided on the adhesion pattern 33.

In embodiments, the material of the restriction members 90, 100, and 110 may be modified. In one example, the restriction members 90, 100, and 110 may be made of a metal material. In this case, the restriction members 90, 100, and 110 may be made of a material different from that of the adhesion pattern 33. The restriction members 90, 100, and 110 may be made of the same material as the adhesion pattern 33 or a surface electrode 30. In this case, the restriction members 90, 100, and 110 may be formed integrally with the adhesion pattern 33 or a surface electrode 30.

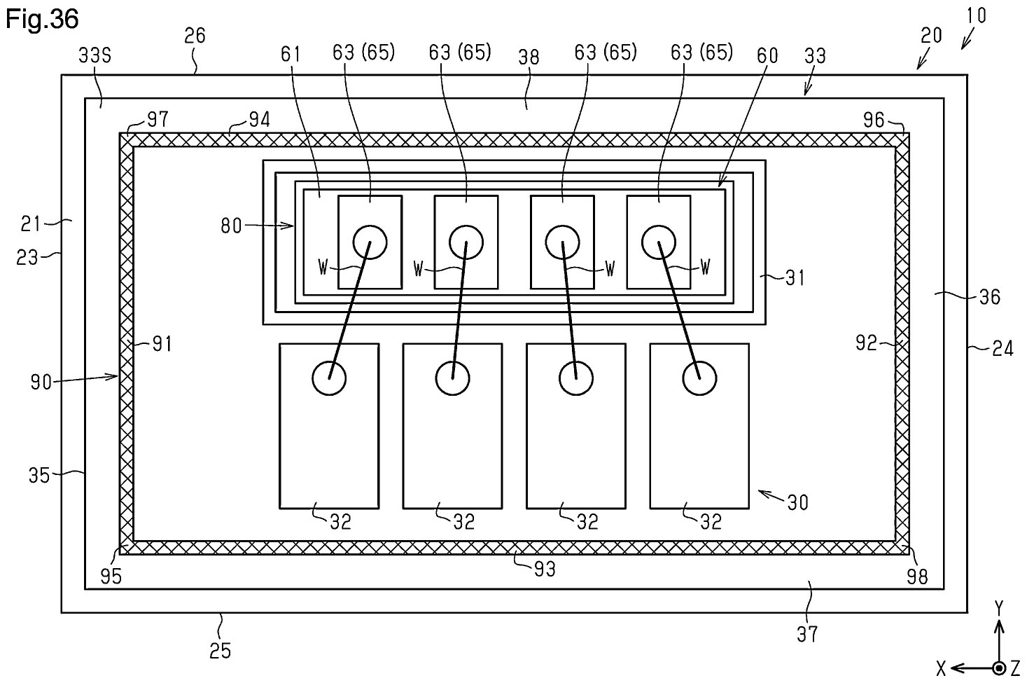

In embodiments, the configuration of the surface electrode 30 may be modified depending on the configuration of the edge-emitting light emitting element 60, for example. In one example, as shown in FIG. 36, the edge-emitting light emitting element 60 includes four light emitting portions 65 (element electrodes 63). The number of wire connection electrodes 32 may be set according to the number of light emitting portions 65 (element electrodes 63), for example. Thus, in the example shown in FIG. 36, the surface electrode 30 includes four wire connection electrodes 32. Each wire connection electrode 32 is rectangular and has a longitudinal direction in the Y-direction and a transverse direction in the X-direction in plan view. The four wire connection electrodes 32 are arranged at the same position in the Y-direction and spaced apart from each other in the X-direction.

Although the edge-emitting light emitting element 60 is used as the semiconductor light emitting element, the configuration of the semiconductor light emitting element is not limited to this. A surface-emitting light emitting device may be used as the semiconductor light emitting element. A vertical cavity surface emitting laser (VCSEL) may be used as an example of a surface-emitting light emitting element. In this case, the cap 70 may be configured such that the upper wall 75 is a light transmission surface. The fourth side wall 74 of the cap 70 may be configured to be translucence as with the first to third side walls 71 to 73. Also, a light emitting diode (LED) may be used as the semiconductor light emitting element.

The above embodiments use the substrate 20 that is made of an insulating material, but there is no limitation to this. The substrate 20 may be made of a metal material such as Cu or Al. In this case, an insulating layer is formed on the front and back surfaces of a flat frame (for example, a metal core) made of Cu, Al, or the like. Multiple surface electrodes 30 and adhesion patterns 33 are formed on the insulating layer (substrate surface 21) formed on the surface of the frame. Multiple back electrodes 40 are formed on the insulating layer (substrate back surface 22) formed on the back surface of the frame. Multiple through-substrate interconnections extend through the frame in the thickness direction (Z-direction) to electrically connect the back electrodes 40 to the corresponding surface electrodes 30. In this case, an insulating layer is formed on the inner surface defining each through-hole formed in the frame. Each through-substrate interconnection is formed to fill the space formed by the insulating layer.

In the above embodiment, the configurations of the substrate 20, the surface electrodes 30, the back electrodes 40, and the through-substrate interconnections may be modified. In one example, instead of the surface electrodes 30, the back electrodes 40, and the through-substrate interconnections, the semiconductor light emitting device 10 may include frames each including a surface electrode 30, a back electrode 40, and a through-substrate interconnection, which are integrally formed, and a substrate, which supports the frames and is made of an insulating material. In this case, the number of the frames corresponds to the number of surface electrodes 30 (back electrodes 40). The substrate is made of an insulating material, which may be epoxy resin, for example. The frames are provided to extend through the substrate in the Z-direction. As such, the sections of the frames exposed from the substrate surface form the surface electrodes 30, and the sections of the frames exposed from the substrate back surface form the back electrodes 40. The adhesion pattern 33 may be formed as a frame extending through the substrate in the Z-direction, or may be formed as a metal layer on the substrate surface. The frame forming the adhesion pattern 33 may be formed by the same frame as the frame in which the surface electrode 30, the back electrode 40, and the through-substrate interconnection are integrated, or may be formed as a different frame.

One or more of the various examples described in this specification may be combined within a range where there is no technical inconsistency.

In this specification, “at least one of A and B” should be understood to mean “only A, or only B, or both A and B.”

Terms such as “first”, “second”, and “third” in this disclosure are used to distinguish subjects and not used for ordinal purposes.

In the present disclosure, the term “on” includes the meaning of “above” in addition to the meaning of “on” unless otherwise clearly indicated in the context. Therefore, for example, the phrase “first component disposed on second component” is intended to mean that the first component may be disposed on the second component in contact with the second component in one embodiment and that the first component may be disposed above the second component without contacting the second component in another embodiment. In other words, the term “on” does not exclude a structure in which another component is formed between the first component and the second component.

The Z-direction referred to in the present disclosure does not necessarily have to be the vertical direction and does not necessarily have to exactly coincide with the vertical direction. In the structures according to the present disclosure, “upward” and “downward” in the z-direction as referred to in the present description are not limited to “upward” and “downward” in the vertical direction. For example, the X-direction may conform to the vertical direction. The Y-direction may conform to the vertical direction.

### CLAUSES

Technical concepts that can be understood from each of the above embodiments and modified examples will now be described. The reference characters used to denote elements of the embodiments are shown in parenthesis for the corresponding elements of the clauses described below. The reference signs used as examples to facilitate understanding, and the elements in each clause are not limited to those elements given with the reference signs.

### Clause 1

A semiconductor light emitting device (10) including:
a substrate (20);
a semiconductor light emitting element (60) mounted on the substrate (20);
an adhesion pattern (33) disposed on the substrate (20) and has a frame shape surrounding the semiconductor light emitting element (60) as viewed from a thickness direction (Z-direction) of the substrate (20);
a cap (70) accommodating the semiconductor light emitting element (60), the cap (70) including a side wall (71 to 74) opposed to the adhesion pattern (33) in the thickness direction (Z-direction), the side wall (71 to 74) having a frame shape and including an opening end surface (76) and a side surface (77, 78);
an adhesive (50) bonding the opening end surface (76) of the side wall (71 to 74) to a pattern surface (33S) of the adhesion pattern (33); and
a restriction member (90) that is disposed on the substrate (20) and is in contact with the side surface (77/78) of the side wall (71 to 74) so as to restrict movement of the cap (70) in a direction (X-direction/Y-direction) intersecting the thickness direction (Z-direction).

### Clause 2

The semiconductor light emitting device according to clause 1, wherein
the side wall (74) includes a light transmission surface configured to transmit light from the semiconductor light emitting element (60), and
the restriction member (90) is configured to restrict movement of the cap (70) in a direction (Y-direction) intersecting the light transmission surface as viewed from the thickness direction (Z-direction).

### Clause 3

The semiconductor light emitting device according to clause 1 or 2, wherein
the restriction member (90) includes:
   a first restriction portion (90A) that is positioned so as not to be aligned with the side wall (71 to 74) as viewed from the thickness direction (Z-direction) and is configured to restrict movement of the cap (70) in a first direction (X-direction) among directions intersecting the thickness direction (Z-direction); and
   a second restriction portion (90B) that is positioned so as not to be aligned with the side wall (71 to 74) as viewed from the thickness direction (Z-direction) and is configured to restrict movement of the cap (70) in a second direction (Y-direction) perpendicular to the first direction (X-direction).

### Clause 4

The semiconductor light emitting device according to clause 3, wherein
the side wall (71 to 74) has a rectangular frame shape including a first corner section (79A), a second corner section (79B), a third corner section (79C), and a fourth corner section (79D),
the restriction member (100/100Q) includes a first member (101) and a second member (102), and
as viewed from the thickness direction (Z-direction), the first member (101) and the second member (102) are placed at positions adjacent to the first corner section (79A) and the second corner section (79B) that are diagonally opposed among the first to fourth corner sections (79A to 79D) of the side wall (71 to 74), so as to form the first restriction portion (100A) and the second restriction portion (100B).

### Clause 5

The semiconductor light emitting device according to clause 4, wherein
the restriction member (100) further includes a third member (103) and a fourth member (104), and
the third member (103) and the fourth member (104) are placed at positions adjacent to the third corner section (79C) and the fourth corner section (79D) that are diagonally opposed among the first to fourth corner sections (79A to 79D), so as to form the first restriction portion (100A) and the second restriction portion (100B).

### Clause 6

The semiconductor light emitting device according to clause 4, wherein
the side wall (71 to 74) includes:
   a first side wall (71) and a second side wall (72) opposed to each other in the first direction (X-direction); and
   a third side wall (73) and a fourth side wall (74) opposed to each other in the second direction (Y-direction),
the first side wall (71) and the third side wall (73) form the first corner section (79A),
the second side wall (72) and the fourth side wall (74) form the second corner section (79B),
as viewed from the thickness direction (Z-direction), the first member (101) includes a section adjacent to the first side wall (71) in the first direction (X-direction) and a section adjacent to the third side wall (73) in the second direction (Y-direction), and
as viewed from the thickness direction (Z-direction), the second member (102) includes a section adjacent to the second side wall (72) in the first direction (X-direction) and a section adjacent to the fourth side wall (74) in the second direction (Y-direction).

### Clause 7

The semiconductor light emitting device according to clause 5, wherein
the side wall (71 to 74) includes:
   a first side wall (71) and a second side wall (72) opposed to each other in the first direction (X-direction); and
   a third side wall (73) and a fourth side wall (74) opposed to each other in the second direction (Y-direction),
the first side wall (71) and the fourth side wall (74) form the third corner section (79C),
the second side wall (72) and the third side wall (73) form the fourth corner section (79D),
as viewed from the thickness direction (Z-direction), the third member (103) includes a section adjacent to the first side wall (71) in the first direction (X-direction) and a section adjacent to the fourth side wall (74) in the second direction (Y-direction), and
as viewed from the thickness direction (Z-direction), the fourth member (104) includes a section adjacent to the second side wall (72) in the first direction (X-direction) and a section adjacent to the third side wall (73) in the second direction (Y-direction).

### Clause 8

The semiconductor light emitting device according to clause 3, wherein
the side wall (71 to 74) has a rectangular frame shape as viewed from the thickness direction (Z-direction),
the side wall (71 to 74) includes:
   a first side wall (71) and a second side wall (72) opposed to each other in the first direction (X-direction);
   a third side wall (73) and a fourth side wall (74) opposed to each other in the second direction (Y-direction),
   a first corner section (79A) formed by the first side wall (71) and the third side wall (73);
   a second corner section (79B) formed by the second side wall (72) and the fourth side wall (74);
   a third corner section (79C) formed by the first side wall (71) and the fourth side wall (74); and
   a fourth corner section (79D) formed by the second side wall (72) and the third side wall (73),
the restriction member (110) includes:
   a first member (111) adjacent to an inner side surface (77) of the side wall (71 to 74) at the first corner section (79A);
   a second member (112) adjacent to the inner side surface (77) of the side wall (71 to 74) at the fourth corner section (79D); and
   a third member (113) adjacent to the outer side surface (78) of the third side wall (73) at a position adjacent to the third side wall (73) in the second direction (Y-direction),
the first member (111) and the second member (112) form the first restriction portion (110A), and
the first member (111), the second member (112), and the third member (113) form the second restriction portion (110B).

### Clause 9

The semiconductor light emitting device according to clause 8, wherein
the first member (111) and the second member (112) each have a rectangular shape having a length direction in the second direction (Y-direction) and a width direction in the first direction (X-direction), and
the third member (113) has a rectangular shape having a length direction in the first direction (X-direction) and a width direction in the second direction (Y-direction).

### Clause 10

The semiconductor light emitting device according to clause 9, wherein
the side wall (71 to 74) has a rectangular frame shape having a longitudinal direction in the first direction (X-direction) and a transverse direction in the second direction (Y-direction) as viewed from the thickness direction (Z-direction), and
the third member (113) has a length dimension (LM3) that is greater than the length dimension (LM1, LM2) of each of the first member (111) and the second member (112).

### Clause 11

The semiconductor light emitting device according to any one of clauses 8 to 10, wherein the semiconductor light emitting element (60) is positioned adjacent to the fourth side wall (74) in the second direction (Y-direction).

### Clause 12

The semiconductor light emitting device according to clause 1, wherein the restriction member (90) has a frame shape surrounding the semiconductor light emitting element (60) as viewed from the thickness direction (Z-direction).

### Clause 13

The semiconductor light emitting device according to clause 12, wherein the restriction member (90) is disposed along the entire extent in a perimeter direction of the inner side surface (77) of the side wall (71 to 74) as viewed from the thickness direction (Z-direction).

### Clause 14

The semiconductor light emitting device according to clause 12, wherein the restriction member (90P) is disposed along the entire extent in a perimeter direction of the outer side surface (78) of the side wall (71 to 74) as viewed from the thickness direction (Z-direction).

### Clause 15

The semiconductor light emitting device according to any one of clauses 1 to 14, wherein the restriction member (90/100/110) is made of an insulating material.

### Clause 16

The semiconductor light emitting device according to clause 15, further including a surface electrode (30) that is disposed on an inner side of the adhesion pattern (33) and is electrically connected to the semiconductor light emitting element (60),
wherein the restriction member (100/110) is disposed on at least one of the adhesion pattern (33) or the surface electrode (30).

### Clause 17

The semiconductor light emitting device according to any one of clauses 1 to 14, wherein the restriction member (90/100/110) is made of a metal material.

### Clause 18

The semiconductor light emitting device according to clause 17, further including a surface electrode (30) that is disposed on an inner side of the adhesion pattern (33) and is electrically connected to the semiconductor light emitting element (60),
wherein the restriction member (100/110) is integral with the adhesion pattern (33) or the surface electrode (30).

### Clause 19

The semiconductor light emitting device according to any one of clauses 1 to 18, wherein the semiconductor light emitting element (60) is an edge-emitting light emitting element configured such that light from the semiconductor light emitting element (60) is emitted to the outside of the semiconductor light emitting device (10) through the side wall (74).

### Clause 20

A method for manufacturing a semiconductor light emitting device (10), the method including:
placing a semiconductor light emitting element (60) on a substrate (820);
applying an adhesive (50) to a pattern surface (33S) of an adhesion pattern (33) on the substrate (820), the adhesion pattern surrounding the semiconductor light emitting element (60) as viewed from a thickness direction (Z-direction) of the substrate (820);
accommodating the semiconductor light emitting element (60) by placing a cap (70) on the adhesive (50), the cap (70) including a side wall (71 to 74) opposed to the adhesion pattern (33) in the thickness direction (Z-direction), the side wall (71 to 74) having a frame shape and including an opening end surface (76) and a side surface (77, 78); and
bonding the cap (70) to the adhesion pattern (33) by curing the adhesive (50), wherein
the substrate (820) includes a restriction member (90) that is disposed on the substrate (820) and is in contact with the side surface (77/78) of the side wall (71 to 74) so as to restrict movement of the cap (70) in a direction (X-direction/Y-direction) intersecting the thickness direction (Z-direction), and
the bonding the cap (70) to the adhesion pattern (33) includes curing the adhesive (50) with a load applied to the cap (70) toward the adhesion pattern (33).

### Clause 21

The method for manufacturing a semiconductor light emitting device according to clause 20, wherein the restriction member (90, 100, 110) is formed by a resist (890) formed on the pattern surface (33S) of the adhesion pattern (33).

### Clause 22

The method for manufacturing a semiconductor light emitting device according to clause 21, wherein
an element surface electrode (31) on which the semiconductor light emitting element (60) is disposed, and a resist pattern (34) formed on the element surface electrode (31) so as to surround the semiconductor light emitting element (60) as viewed from the thickness direction (Z-direction) of the substrate (820) are formed on the substrate (820), and
the restriction member (90) and the resist pattern (34) are formed in a common step.

### Clause 23

The method for manufacturing a semiconductor light emitting device according to clause 22, wherein the restriction member (90) and the resist pattern (34) are formed by a common resist (890).

The above description is merely exemplary. Descriptions of features in each example are to be considered as being applicable to similar features or aspects in other examples. Suitable results may be achieved if sequences are performed in a different order, and/or if components in a described system, architecture, device, or circuit are combined differently, and/or replaced or supplemented by other components or their equivalents. The present disclosure is intended to include any substitute, modification, changes included in the scope of the disclosure including the claims.

Various changes in form and details may be made to the examples above without departing from the spirit and scope of the claims and their equivalents. The examples are for the sake of description only, and not for purposes of limitation. Descriptions of features in each example are to be considered as being applicable to similar features or aspects in other examples. Suitable results may be achieved if sequences are performed in a different order, and/or if components in a described system, architecture, device, or circuit are combined differently, and/or replaced or supplemented by other components or their equivalents. The scope of the disclosure is not defined by the detailed description, but by the claims and their equivalents. All variations within the scope of the claims and their equivalents are included in the disclosure.

What is claimed is:

1. A semiconductor light emitting device, comprising:
a substrate;
a semiconductor light emitting element mounted on the substrate;
an adhesion pattern that is disposed on the substrate and has a frame shape surrounding the semiconductor light emitting element as viewed from a thickness direction of the substrate;
a cap accommodating the semiconductor light emitting element, the cap including a side wall opposed to the adhesion pattern in the thickness direction, the side wall having a frame shape and including an opening end surface and a side surface;
an adhesive bonding the opening end surface of the side wall to a pattern surface of the adhesion pattern; and
a restriction member that is disposed on the substrate and is in contact with the side surface of the side wall so as to restrict movement of the cap in a direction intersecting the thickness direction.

2. The semiconductor light emitting device according to claim 1, wherein
the side wall includes a light transmission surface configured to transmit light from the semiconductor light emitting element, and
the restriction member is configured to restrict movement of the cap in a direction intersecting the light transmission surface as viewed from the thickness direction.

3. The semiconductor light emitting device according to claim 1, wherein the restriction member includes:
a first restriction portion that is positioned so as not to be aligned with the side wall as viewed from the thickness direction and is configured to restrict movement of the cap in a first direction among directions intersecting the thickness direction; and
a second restriction portion that is positioned so as not to be aligned with the side wall as viewed from the thickness direction and is configured to restrict movement of the cap in a second direction perpendicular to the first direction.

4. The semiconductor light emitting device according to claim 3, wherein
the side wall has a rectangular frame shape including a first corner section, a second corner section, a third corner section, and a fourth corner section,
the restriction member includes a first member and a second member, and
as viewed from the thickness direction, the first member and the second member are placed at positions adjacent to the first corner section and the second corner section that are diagonally opposed among the first to fourth corner sections of the side wall, so as to form the first restriction portion and the second restriction portion.

5. The semiconductor light emitting device according to claim 4, wherein
the restriction member includes a third member and a fourth member, and
the third member and the fourth member are placed at positions adjacent to the third corner section and the fourth corner section that are diagonally opposed among the first to fourth corner sections, so as to form the first restriction portion and the second restriction portion.

6. The semiconductor light emitting device according to claim 4, wherein
the side wall includes:
a first side wall and a second side wall opposed to each other in the first direction; and
a third side wall and a fourth side wall opposed to each other in the second direction,
the first side wall and the third side wall form the first corner section,
the second side wall and the fourth side wall form the second corner section,
as viewed from the thickness direction, the first member includes a section adjacent to the first side wall in the first direction and a section adjacent to the third side wall in the second direction, and
as viewed from the thickness direction, the second member includes a section adjacent to the second side wall in the first direction and a section adjacent to the fourth side wall in the second direction.

7. The semiconductor light emitting device according to claim 5, wherein
the side wall includes:
a first side wall and a second side wall opposed to each other in the first direction; and
a third side wall and a fourth side wall opposed to each other in the second direction,
the first side wall and the fourth side wall form the third corner section,
the second side wall and the third side wall form the fourth corner section,
as viewed from the thickness direction, the third member includes a section adjacent to the first side wall in the first direction and a section adjacent to the fourth side wall in the second direction, and
as viewed from the thickness direction, the fourth member includes a section adjacent to the second side wall in the first direction and a section adjacent to the third side wall in the second direction.

8. The semiconductor light emitting device according to claim 3, wherein
the side wall has a rectangular frame shape as viewed from the thickness direction,
the side wall includes:
a first side wall and a second side wall opposed to each other in the first direction;
a third side wall and a fourth side wall opposed to each other in the second direction;
a first corner section formed by the first side wall and the third side wall;
a second corner section formed by the second side wall and the fourth side wall;
a third corner section formed by the first side wall and the fourth side wall; and
a fourth corner section formed by the second side wall and the third side wall,
the restriction member includes:
a first member adjacent to an inner side surface of the side wall at the first corner section;
a second member adjacent to the inner side surface of the side wall at the fourth corner section; and
a third member adjacent to an outer side surface of the third side wall at a position adjacent to the third side wall in the second direction,
the first member and the second member form the first restriction portion, and
the first member, the second member, and the third member form the second restriction portion.

9. The semiconductor light emitting device according to claim 8, wherein
the first member and the second member each have a rectangular shape having a length direction in the second direction and a width direction in the first direction, and
the third member has a rectangular shape having a length direction in the first direction and a width direction in the second direction.

10. The semiconductor light emitting device according to claim 9, wherein
the side wall has a rectangular frame shape having a longitudinal direction in the first direction and a transverse direction in the second direction as viewed from the thickness direction, and
the third member has a length dimension that is greater than a length dimension of each of the first and second members.

11. The semiconductor light emitting device according to claim 8, wherein the semiconductor light emitting element is positioned adjacent to the fourth side wall in the second direction.

12. The semiconductor light emitting device according to claim 1, wherein the restriction member has a frame shape surrounding the semiconductor light emitting element as viewed from the thickness direction.

13. The semiconductor light emitting device according to claim 12, wherein the restriction member is disposed along an entire extent in a perimeter direction of an inner side surface of the side wall as viewed from the thickness direction.

14. The semiconductor light emitting device according to claim 12, wherein restriction member is disposed along an entire extent in a perimeter direction of an outer side surface of the side wall as viewed from the thickness direction.

15. The semiconductor light emitting device according to claim 1, wherein the restriction member is made of an insulating material.

16. The semiconductor light emitting device according to claim 15, further comprising a surface electrode that is disposed on an inner side of the adhesion pattern and is electrically connected to the semiconductor light emitting element,
wherein the restriction member is disposed on at least one of the adhesion pattern or the surface electrode.

17. The semiconductor light emitting device according to claim 1, wherein the restriction member is made of a metal material.

18. The semiconductor light emitting device according to claim 17, further comprising a surface electrode that is disposed on an inner side of the adhesion pattern and is electrically connected to the semiconductor light emitting element,
wherein the restriction member is integral with the adhesion pattern or the surface electrode.

19. The semiconductor light emitting device according to claim 1, wherein the semiconductor light emitting element is an edge-emitting light emitting element configured such that light from the semiconductor light emitting element is emitted to an outside of the semiconductor light emitting device through the side wall.

20. A method for manufacturing a semiconductor light emitting device, the method comprising:
placing a semiconductor light emitting element on a substrate;
applying an adhesive to a pattern surface of an adhesion pattern on the substrate, the adhesion pattern surrounding the semiconductor light emitting element as viewed from a thickness direction of the substrate;
accommodating the semiconductor light emitting element by placing a cap on the adhesive, the cap including a side wall opposed to the adhesion pattern in the thickness direction, the side wall having a frame shape and including an opening end surface and a side surface; and
bonding the cap to the adhesion pattern by curing the adhesive, wherein
the substrate includes a restriction member that is disposed on the substrate and is in contact with the side surface of the side wall so as to restrict movement of the cap in a direction intersecting the thickness direction, and
the bonding the cap to the adhesion pattern includes curing the adhesive with a load applied to the cap toward the adhesion pattern.
